(19) United States
(12) Patent Application Publication
(10) Pub. No.: US 2025/0316951 A1
(43) Pub. Date: Oct. 9, 2025

(54) LASER DEVICE

(71) Applicant: Hisense Laser Display Co., Ltd, Qingdao City (CN)

(72) Inventors: Zinan ZHOU, Qingdao City (CN); Xin ZHANG, Qingdao City (CN); Youliang TIAN, Qingdao City (CN); Yao LU, Qingdao City (CN); Zhaoshi GUO, Qingdao City (CN); Kuanlin CHEN, Qingdao City (CN)

(73) Assignee: Hisense Laser Display Co., Ltd, Qingdao City (CN)

(21) Appl. No.: 19/246,776

(22) Filed: Jun. 24, 2025

Related U.S. Application Data
(63) Continuation of application No. PCT/CN2023/134102, filed on Nov. 24, 2023.

(30) Foreign Application Priority Data
Jan. 10, 2023 (CN) 202310033068.9
Jan. 10, 2023 (CN) 202310033081.4
Jan. 10, 2023 (CN) 202310033082.9

(51) Int. Cl. H01S 5/02257; H01S 5/02253

(52) U.S. Cl. CPC H01S 5/02257; H01S 5/02253

(57) ABSTRACT

A laser device includes a substrate, a first frame, at least one packaging structure, at least one light-emitting chip, a target optical element and a first cover. The first frame is fixed to the substrate to define a first accommodating space. The packaging structure is located in the first accommodating space and forms a second accommodating space. The light-emitting chip is located in the second accommodating space and configured to emit laser beams. The target optical element is located in the first accommodating space. The first cover is fixed to a side of the first frame away from the substrate. The packaging structure includes a target side wall, located on a light exit side of the light-emitting chip and the target side wall is light-transmissive. The laser beams emitted from the light-emitting chip is transmitted to the target optical element through the target side wall.

### CROSS-REFERENCE TO RELATED APPLICATIONS

This application is a continuation application of International Application No. PCT/CN2023/134102, filed on Nov. 24, 2023, which claims priority to Chinese Patent Application No. 202310033082.9, filed on Jan. 10, 2023; Chinese Patent Application No. 202310033068.9, filed on Jan. 10, 2023; and Chinese Patent Application No. 202310033081.4, filed on Jan. 10, 2023, which are incorporated herein by reference in their entireties.

### TECHNICAL FIELD

The present disclosure relates to the field of photoelectric technologies, and in particular, to a laser device.

### BACKGROUND

With the development of photoelectric technologies, laser devices have been widely used, and consumers have higher and higher requirements for the luminous effect of laser devices.

### SUMMARY

A laser device is provided. The laser device includes a substrate, a first frame, at least one packaging structure, at least one light-emitting chip, a target optical element and a first cover. The first frame is fixed to the substrate so as to define a first accommodating space. Any one of the at least one packaging structure is located in the first accommodating space, and a second accommodating space is formed in the packaging structure. Any one of the at least one light-emitting chip is located in the second accommodation space and configured to emit laser beams. The target optical element is located in the first accommodating space. The first cover is fixed to a side of the first frame away from the substrate and configured to seal the first accommodating space. The packaging structure includes a target side wall, the target side wall is located on a light exit side of the light-emitting chip and is light-transmissive, the laser beams emitted by the light-emitting chip are directed toward the target optical element through the target side wall, and the target optical element is configured to exit the received laser beams out of the first accommodating space.

### BRIEF DESCRIPTION OF THE DRAWINGS

FIG. 1 is a diagram showing a structure of a laser device, in accordance with some embodiments;

FIG. 2 is a diagram showing a structure of another laser device, in accordance with some embodiments;

FIG. 3 is a diagram showing a structure of a packaging structure of a laser device, in accordance with some embodiments;

FIG. 4 is a diagram showing a structure of yet another laser device, in accordance with some embodiments;

FIG. 5 is a diagram showing a structure of yet another laser device, in accordance with some embodiments;

FIG. 6 is a diagram showing a structure of yet another laser device, in accordance with some embodiments;

FIG. 7 is a diagram showing a structure of yet another laser device, in accordance with some embodiments;

FIG. 8 is a diagram showing a structure of yet another laser device, in accordance with some embodiments;

FIG. 9 is a diagram showing a structure of yet another laser device, in accordance with some embodiments;

FIG. 10 is a diagram showing a structure of yet another laser device, in accordance with some embodiments;

FIG. 11 is a diagram showing a structure of yet another laser device, in accordance with some embodiments;

FIG. 12 is a diagram showing a structure of yet another laser device, in accordance with some embodiments;

FIG. 13 is a diagram showing a partial structure of yet another laser device, in accordance with some embodiments;

FIG. 14 is a diagram showing a structure of yet another laser device, in accordance with some embodiments;

FIG. 15 is a top view of the laser device in FIG. 14;

FIG. 16 is a diagram showing a structure of yet another laser device, in accordance with some embodiments;

FIG. 17 is a top view of the laser device in FIG. 16;

FIG. 18 is a diagram showing a structure of yet another laser device, in accordance with some embodiments;

FIG. 19 is a top view of the laser device in FIG. 18;

FIG. 20 is a diagram showing a structure of yet another laser device, in accordance with some embodiments;

FIG. 21 is a top view of the laser device in FIG. 20;

FIG. 22 is a diagram showing a structure of yet another laser device, in accordance with some embodiments;

FIG. 23 is a diagram showing a structure of another packaging structure of a laser device, in accordance with some embodiments;

FIG. 24 is a diagram showing a structure of yet another laser device, in accordance with some embodiments;

FIG. 25 is a diagram showing a structure of yet another laser device, in accordance with some embodiments;

FIG. 26 is a diagram showing a structure of yet another laser device, in accordance with some embodiments;

FIG. 27 is a diagram showing a structure of yet another laser device, in accordance with some embodiments;

FIG. 28 is a diagram showing a structure of yet another laser device, in accordance with some embodiments;

FIG. 29 is a diagram showing a structure of yet another laser device, in accordance with some embodiments;

FIG. 30 is a diagram showing a structure of yet another laser device, in accordance with some embodiments;

FIG. 31 is a diagram showing a structure of yet another laser device, in accordance with some embodiments;

FIG. 32 is a diagram showing a structure of yet another laser device, in accordance with some embodiments;

FIG. 33 is a diagram showing a structure of yet another laser device, in accordance with some embodiments;

FIG. 34 is an exploded view of the laser device shown in FIG. 33;

FIG. 35 is a diagram showing a structure of yet another laser device, in accordance with some embodiments;

FIG. 36 is an exploded view of the laser device shown in FIG. 35;

FIG. 37 is a diagram showing a structure of yet another laser device, in accordance with some embodiments;

FIG. 38 is a perspective view of yet another laser device, in accordance with some embodiments;

FIG. 39 is a diagram showing a structure of yet another laser device, in accordance with some embodiments;

FIG. 40 is a diagram showing a structure of yet another laser device, in accordance with some embodiments;

FIG. 41 is a perspective view of the laser device shown in FIG. 40;

FIG. 42 is an exploded view of the laser device shown in FIG. 40;

FIG. 43 is a diagram showing a structure of yet another laser device, in accordance with some embodiments;

FIG. 44 is a diagram showing a structure of yet another laser device, in accordance with some embodiments;

FIG. 45 is a diagram showing a structure of yet another laser device, in accordance with some embodiments;

FIG. 46 is a diagram showing a structure of yet another laser device, in accordance with some embodiments;

FIG. 47 is a diagram showing a structure of yet another laser device, in accordance with some embodiments;

FIG. 48 is a diagram showing a structure of a laser assembly, in accordance with some embodiments; and

FIG. 49 is a diagram showing a structure of another laser assembly, in accordance with some embodiments.

### DETAILED DESCRIPTION

Some embodiments of the present disclosure will be clearly and completely described below with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.” In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments or examples in any suitable manner.

The terms “first” and “second” are used for descriptive purposes only and are not to be construed as indicating or implying a relative importance or implicitly indicating the number of indicated technical features. Thus, features defined by “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled,” “connected,” and derivatives thereof may be used. The term “connected” should be understood in a broad sense. For example, the term “connected” may represent a fixed connection, a detachable connection, or a one-piece connection, or may represent a direct connection, or may represent an indirect connection through an intermediate medium. The term “coupled” indicates that two or more components are in direct physical or electrical contact with each other. The term “coupled” or “communicatively coupled” may also mean that two or more components are not in direct contact with each other but still cooperate or interact with each other. The embodiments disclosed herein are not necessarily limited to the content herein.

The phrase “at least one of A, B, and C” has the same meaning as the phrase “at least one of A, B, or C,” both including the following combinations of A, B, and C, only A, only B, only C, a combination of A and B, a combination of A and C, a combination of B and C, and a combination of A, B, and C.

The phrase “A and/or B” includes the following three combinations: only A, only B, and a combination of A and B.

The use of “applicable to” or “configured to” herein indicates an open and inclusive expression, which does not exclude devices that are applicable to or configured to perform additional tasks or steps.

The term “about”, “substantially” or “approximately” as used herein includes a stated value and an average value within an acceptable range of deviation of a particular value, the acceptable range of deviation is determined by a person of ordinary skill in the art in consideration of the measurement in question and errors associated with the measurement of a particular quantity (i.e., limitations of the measurement system).

The term such as “parallel,” “perpendicular,” or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°. The term “equal” includes absolute equality and approximate equality, and an acceptable range of deviation of the approximate equality may be that, for example, a difference between the two that are equal is less than or equal to 5% of either of the two.

Some embodiments of the present disclosure provide a projection apparatus. The projection apparatus may include a laser source assembly, a light valve and a lens. Laser beams emitted by the light source assembly may directed toward the light valve, modulated by the light valve, and then directed toward the lens, so that the lens may project the received laser beams to form a projection image. The light source assembly includes a laser device, a light homogenizing component (e.g., a light pipe), a shaping component and a converging lens. The light homogenizing component is configured to homogenize the laser beams emitted by the laser device; the shaping component may shape the light spot into a shape required to form a projection image; and the converging lens may converge the laser beams into subsequent components.

In the related art, the laser device includes a base plate, a frame, a light-emitting chip and a reflective component. The base plate and the frame are fixed to enclose an accommodating space. The light-emitting chip and the reflective component are located in the accommodating space and are fixed on the base plate. The light-emitting chip emits laser beams to a corresponding reflective component (e.g., a reflecting prism), and the reflective component reflects the received laser beams in a direction away from the base plate. The mounting accuracy of the reflective component will directly affect the light exit of the laser device.

In order to prevent the light-emitting chip from being damaged by moisture in the environment during the use of the laser device, the accommodating space of the laser device needs to be sealed after the light-emitting chip and the reflecting prism have been mounted. For example, the laser device further includes a sealing cover. The sealing cover is located at a side of the frame away from the base plate and is configured to seal the accommodating space.

If the light-emitting chip is powered on and lit before the accommodating space is sealed, the moisture in the environment will accelerate the aging of the light-emitting chip and even cause catastrophical optical damage (COD) to the light-emitting chip. Therefore, in the related art, the light-emitting chip and the reflective component each are adopted a manner of passive mounting.

When preparing the laser device, the light-emitting chip and the reflective component are directly mounted on the base plate according to the preset positions, and then the accommodating space is sealed with the sealing cover. During the mounting process, the positions of the light-emitting chip and the reflective component are fine-tuned based on the set distance. Afterwards, the light-emitting chip is turned on. The light-emitting chip is configured to emit laser beams toward the reflective component, and the reflective component is configured to reflect the received laser beams in the direction away from the base plate.

However, certain errors may inevitably exist in the mounting process of the component. For example, there is an error in the mounting position of the reflective component in the laser device, which will cause the path of the laser beams emitted by the light-emitting chip deviate from the required path after being reflected by the reflective component, and make the laser beams actually emitted by the laser device unable to meet the demand, thereby affecting the light-emitting effect of the laser device.

In this mounting manner, if there is a large error between the irradiation conditions of the laser beams emitted by the light-emitting chip on the reflective component (e.g., the irradiation position of the laser beams, the size and shape of the formed light spot, etc.) and the required irradiation conditions, since the laser device has been encapsulated, it is difficult to readjust the mounting position of the reflective component and the process is complicated. If the reflective component is not adjusted, the laser beams emitted by the laser device may not be effectively utilized, and the subsequent assembly with other components will also be difficult.

To solve the above problem, some embodiments of the present disclosure provide a laser device.

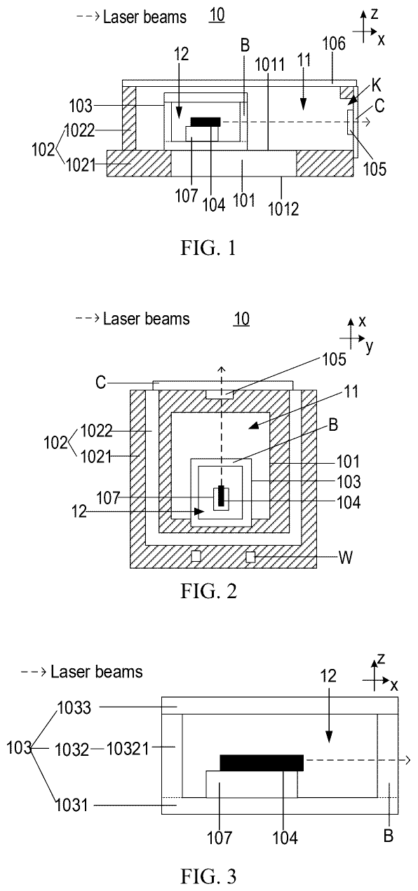

Referring to FIGS. 1 and 2, the laser device 10 includes a substrate 101, a first frame 102, a packaging structure 103 (e.g., a first packaging structure), a light-emitting chip 104, a wavelength conversion component 105, and a first cover 106 (e.g., a sealing cover).

The substrate 101 is fixed to the first frame 102 to define a first accommodating space 11 between the substrate 101 and the first frame 102. The substrate 101 forms a bottom of the first accommodating space 11, and the first frame 102 forms a portion of a side wall of the first accommodating space 11. Here, the structure composed of the substrate 101 and the first frame 102 may be referred to as a tube shell.

The first cover 106 is fixed to a side of the first frame 102 away from the substrate 101 and is configured to seal the first accommodating space 11.

The light-emitting chip 104 is disposed in the packaging structure 103. Each one of the packaging structure 103 and the wavelength conversion component 105 is disposed in the first accommodating space 11. The substrate 101, the first frame 102 and the first cover 106 may be configured into a packaging structure (e.g., a second packaging structure) to encapsulate the components in the first accommodating space 11 through the packaging structure.

In this way, external substances such as water and oxygen may be prevented from corroding each component in the first accommodating space 11 to ensure the working reliability of each component, so that it is conducive to prolonging the lifespan of the laser device.

In some embodiments, the packaging structure 103 is configured to form a second accommodating space 12, and the light-emitting chip 104 is located in the second accommodating space 12. Solder (e.g., gold-tin solder) may be pre-placed on the bottom edge of the first cover 106, and the first cover 106 and the first frame 102 may be fixed by means of high-temperature welding to seal the second accommodating space 12.

Referring to FIGS. 3 to 5, the second accommodating space 12 may be formed by the packaging structure 103 independently. Alternatively, the second accommodating space 12 may be formed by the packaging structure 103 together with components such as the substrate 101 and the first frame 102, and the like, which will be described later.

In some embodiments, the packaging structure 103 includes a target side wall B. The target side wall B is located on a light exit side of the light-emitting chip 104. The target side wall B may transmit light. The light-emitting chip 104 is configured to emit laser beams toward the target side wall B. The laser beams are adapted to pass through the target side wall B and exit out of the packaging structure 103.

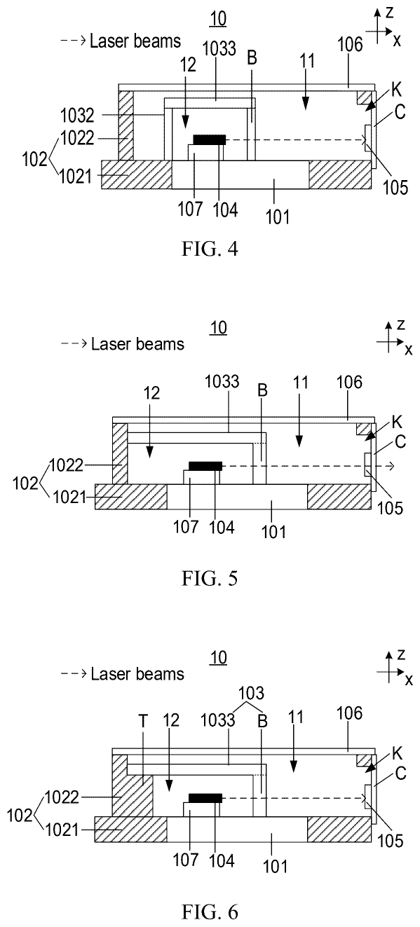

Referring to FIG. 4, the wavelength conversion component 105 is located in a transmission path of the laser beams transmitted from the packaging structure 103. After the laser beams are directed toward the wavelength conversion component 105, the wavelength conversion component 105 may be excited to emit light with a wavelength different from that of the laser beams, so as to achieve wavelength conversion of the laser beams.

In some embodiments of the present disclosure, the wavelength conversion component 105 is formed of a fluorescent material. The wavelength conversion component 105 may emit fluorescence under the excitation of the laser beams, and the color of the fluorescence is different from the color of the laser beams.

For example, the laser beams may be blue laser beams, and the fluorescence may be yellow laser beams, green laser beams, red laser beams, or the like. The wavelength conversion component 105 is a yttrium aluminum garnet (YAG) phosphor. The wavelength conversion component 105 may be in a shape of a sheet, a plate or a block.

Referring to FIG. 1, considering an example in which the fluorescence emitted by the wavelength conversion component 105 passes through a light-transmissive side wall of the first frame 102 and then exits out of the first accommodating space 11. Of course, the laser device 10 may also have other light-emitting manners (which will be described below).

In the related art, if fluorescence is to be obtained, a light path shaping component is usually used to focus the blue laser beams emitted by a laser device onto a fluorescent wheel to excite the fluorescent wheel to emit fluorescence. However, this type of fluorescence excitation system requires more lenses and devices, the light path is complicated, and the system size is large.

In some embodiments, the laser device 10 may use the wavelength conversion component 105 to convert the wavelength of the laser beams so that the laser device 10 emits fluorescence with a color different from the color of the laser beams, thereby improving the flexibility of use of the laser device 10.

In this way, there is no need to set up more additional lenses and devices, the manner of emitting fluorescence is relatively simple, and the size of the device emitting fluorescence is relatively small. Moreover, the wavelength conversion component 105 may be protected by disposing the wavelength conversion component 105 in the accommodating space of the laser device 10, thereby facilitating improving the working reliability of the wavelength conversion component 105.

In some embodiments, the substrate 101, the first frame 102, and the first cover 106 are jointly provide the encapsulation of the entire laser device 10. After the packaging structure 103 performs a primary encapsulation on the light-emitting chip 104, the first cover 106, the substrate 101 and the first frame 102 may realize a secondary encapsulation of the light-emitting chip 104, as well as encapsulation of components such as the packaging structure 103, the wavelength conversion component 105 or the reflective component 108 (as shown in FIG. 8). When assembling the laser device 10, the light-emitting chip 104 may be encapsulated in the first accommodating space 11 by the packaging structure 103, after which the wavelength conversion component 105 may be mounted, and then the first cover 106 may be fixed on the side of the first frame 102 away from the substrate 101.

In the related art, the airtightness level of the sealed space after sealing is required to reach 10⁻⁸ Pascal cubic meters per second (Pa·m³/s) or above. The airtightness requirement is relatively high, and the requirements for the encapsulation process and the encapsulation materials used are also relatively high, so the encapsulation difficulty of the second accommodating space 12 of the laser device 10 is relatively high.

In some embodiments of the present disclosure, the airtightness level of the second accommodating space 12 formed by the packaging structure 103 may reach 10⁻⁵ Pa cubic meters per second, which is lower than the airtightness level of the sealed space in the related art. Afterwards, the first cover 106 is configured to encapsulate the first accommodating space 11, and the airtightness level of the packaging is lower than the airtightness level of the enclosed space in the related art. For example, the first cover 106 may be fixed by means of sealing glue with medium airtightness effect. The encapsulation of the first accommodating space 11 and the encapsulation of the second accommodating space 12 may enable the environment where the light-emitting chip 104 is located meet the airtightness requirement. In this way, the requirements for the encapsulation process may be lowered and the encapsulation difficulty may be reduced on the basis of meeting the airtightness requirements of the laser device 10.

In some embodiments, the light-emitting chip 104 may be lighted during the mounting process of the wavelength conversion component 105. Since the light-emitting chip 104 has been sealed by the packaging structure 103, lighting the light-emitting chip 104 will not cause damage to the light-emitting chip 104 from external pollutants, and the working reliability of the light-emitting chip 104 may still be guaranteed.

After lighting up the light-emitting chip 104, the wavelength conversion component 105 may be adjusted to an appropriate position based on the irradiation conditions of the laser beams emitted by the light-emitting chip 104 (e.g., the irradiation position of the laser beams, and the size and shape of the formed light spot, etc.), thereby ensuring the excitation effect of the laser beams on the wavelength conversion component 105.

If the first accommodating space 11 of the laser device 10 is also provided with components (e.g., a reflective component or a collimating lens) through which the laser beams need to pass, in this case, the mounting positions of the above components may also be determined based on the irradiation conditions of the laser beams emitted by the light-emitting chip 104. As a result, active adjustment of the component in the laser device 10 that needs to be irradiated by the laser beams may be achieved, thereby facilitating improving the mounting accuracy of the component and improving the light-emitting effect of the laser device 10.

In some embodiments, referring to FIG. 1, the laser device 10 further includes a heat sink. The heat sink 107 corresponds to the light-emitting chip 104. For example, in a case where the laser device 10 includes a plurality of light-emitting chips 104 and a plurality of heat sinks 107, each light-emitting chip 104 is located on a corresponding heat sink 107, so that the heat of the corresponding light-emitting chip 104 is dissipated through the heat sink 107.

It should be noted that, since the heat generated by the light-emitting chip 104 will be transmitted and dissipated vertically downward, the heat sink 107 may assist the corresponding light-emitting chip 104 in dissipating heat, and the heat may be dissipated normally even if the light-emitting chip 104 is located in the second accommodating space 12, and the packaging structure 103 will not affect the heat dissipation effect of the light-emitting chip 104. The heat sink 107 may also assist a corresponding laser emitting chip 104 to be electrically connected.

The thermal expansion coefficient of the heat sink 107 is proximate to that of the light-emitting chip 104, which may alleviate the stress generated during the temperature change of the material. For example, the material of the heat sink 107 may be ceramic or the like. The light-emitting chip 104 and the heat sink 107 may be formed by means of eutectic welding, an upper surface of the light-emitting chip 104 and a lower surface of the heat sink 107 each may provide with a gold-plated layer, and mounting surfaces of the light-emitting chip 104 and the heat sink 107 may be pre-set with solder, and the mounting of the light-emitting chip 104 and the heat sink 107 may be achieved through the solder.

In some embodiments, the substrate 101 includes a first surface 1011 and a second surface 1012 disposed in a thickness direction thereof. The first surface 1011 is parallel to the second surface 1012 and the first surface 1011 is closer to the first accommodating space 11 than the second surface 1012. Referring to FIGS. 1 and 2, the first frame 102 includes an annular plate 1021 and a plurality of first side walls 1022. The plurality of first side walls are disposed on the annular plate 1021 and are sequentially fixedly connected to the annular plate 1021. The first accommodating space 11 is enclosed by the plurality of first side walls 1022.

The first frame 102 includes four first side walls 1022 connected in sequence, and the annular plate 1021 is in a shape of a square ring. The substrate 101 is rectangular and includes four side surfaces. The annular plate 1021 of the first frame 102 may enclose the substrate 101, and an inner annular surface of the annular plate 1021 is fixed to the side surface of the substrate 101.

The light-emitting chip 104 is located on the substrate 101, and an orthographic projection of the light-emitting chip 104 may be located on the substrate 101. The thermal conductivity of the substrate 101 is good, in this way, the substrate 101 may assist the light-emitting chip 104 in dissipating heat.

For example, the material of the substrate 101 may include oxygen-free copper, or a composite material of diamond and copper (also referred to as diamond copper). The first frame 102 may be made of ceramic, aluminum oxide, aluminum nitride, or the like. Since the difference in thermal expansion coefficients between aluminum oxide and diamond copper is small, the substrate 101 is connected to the first frame 102 by means of brazing, which may improve the assembly effect.

In some embodiments, at least a portion of the packaging structure 103 is located on the substrate 101. For example, the entire orthographic projection of the packaging structure 103 is located on the substrate 101, or a portion of the orthographic projection of the packaging structure 103 is located on the annular plate 1021. In some embodiments, the laser device 10 further includes a first conductive structure. Referring to FIG. 2, the first conductive structure W is disposed in the annular plate 1021. FIG. 2 illustrates an exposed portion of the first conductive structure W located outside the enclosed region of the first frame 102.

The light-emitting chip 104 may be electrically connected to an end of the first conductive structure W. The other end of the first conductive structure W may be electrically connected to an external circuit, in this way, current may be transmitted to the light-emitting chip 104 through the first conductive structure W to excite the light-emitting chip 104 to emit laser beams.

In some embodiments, the material of the annular plate 1021 includes ceramic. The first conductive structure W may be embedded in the annular plate 1021. In some embodiments, the first conductive structure W may also be disposed in the side wall 1022 of the first frame 102 proximate to the light-emitting chip 104.

In some embodiments, the first accommodating space 11 may be enclosed by the substrate 101 and a plurality of first side walls 1022. The plurality of first side walls 1022 may be disposed on an upper end surface of the substrate 101 to enclose the first accommodating space 11.

In some embodiments, the plurality of first side walls 1022 may also be disposed on an outer side of the substrate 101 to enclose the first accommodating space 11.

In some embodiments, referring to FIGS. 1 to 3, the packaging structure 103 in the laser device 10 is configured to seal the light-emitting chip 104, and the packaging structure 103 may independently define the second accommodating space 12.

In some embodiments, the packaging structure 103 may also define the second accommodating space 12 together with other components. For example, referring to FIG. 4, the packaging structure 103 and the substrate 101 together define the second accommodating space 12. Referring to FIG. 5, the packaging structure 103, the first frame 102 and the substrate 101 together define the second accommodating space 12.

Various implementations of the second accommodating space 12 are described below.

Referring to FIGS. 1 and 3, the packaging structure 103 independently forms the second accommodating space 12 for placing the light-emitting chip 104.

For example, referring to FIG. 3, the packaging structure 103 includes a base plate 1031, a second frame 1032, and a second cover 1033. The second frame 1032 includes a second side wall 10321. The base plate 1031, the second frame 1032 and the second cover 1033 define the second accommodating space 12 to place the light-emitting chip 104.

Here, the base plate 1031, the second frame 1032 and the second cover 1033 may be three independent components respectively. Alternatively, the base plate 1031, the second cover 1033, and the second frame 1032 are formed as a one-piece member.

The base plate 1031 and the second cover 1033 each are in a shape of a plate, and the second frame 1032 includes four second side walls 10321. The enclosed region of the four second side walls 10321 is substantially in a shape of a rectangle. The base plate 1031 is fixed to the second frame 1032. The light-emitting chip 104 is located on the base plate 1031 and is enclosed by the second frame 1032. The second cover 1033 is fixed to a side of the second frame 1032 away from the base plate 1031. The components in the packaging structure 103 may be fixed by means of a sealant.

In some embodiments, the second frame 1032 includes the target side wall B. A second side wall 10321 located on the light exit side of the light-emitting chip 104 among the four second side walls 10321 is configured as the target side wall B mentioned above. That is to say, the target side wall B in the second frame 1032 is located at the light exit side of the light-emitting chip 104.

In addition, the target side wall B needs to be light-transmissive, and the material of the target side wall B includes glass, sapphire, quartz or transparent ceramics. Referring to FIG. 3, the light-emitting chip 104 may emit laser beams along x-direction, and the laser beams may exit by passing through the target side wall B of the packaging structure 103.

Referring to FIG. 4, the second frame 1032 includes a frame-shaped portion and a light-transmitting portion. An opening is formed on a side of the frame-shaped portion proximate to the light exit side of the light-emitting chip 104. The light-transmitting portion is arranged at the above-mentioned opening. A side wall of the frame-shaped portion provided with the opening is the above-mentioned target side wall B. An end of the frame-shaped portion is fixed to a surface formed by the substrate 101 and the annular plate 1021, and another end of the frame-shaped portion is fixed to the second cover 1033.

In some embodiments, the second cover 1033, the target side wall B and the frame portion may be three independent components respectively. Alternatively, the second cover 1033 and the target side wall B may be a one-piece member; the second cover 1033 may also be formed as a one-piece member with the frame portion.

The frame-shaped portion and the light-transmitting portion may be made of different materials. The light-transmitting portion is made of a light-transmitting material, and the frame-shaped portion may be made of a light-opaque material. For example, the material of the frame-shaped portion may include metal or ceramic.

Alternatively, the material of the frame-shaped portion may be the same as that of the target side wall B, and the frame-shaped portion may also be made of a light-transmitting material, the present disclosure is not limited thereto.

In some embodiments, the surfaces of the packaging structure 103 except the target side wall B each may be coated with a light absorbing material layer. In this way, stray light mixed into the packaging structure 103 may be absorbed through the light absorbing material layer, thereby improving the light exit effect of the laser device 10.

The laser device further includes a second conductive structure, the second conductive structure is disposed in the base plate 1031 or the second frame 1032 and communicates with the inside and outside of the second accommodating space 12.

Referring to FIG. 2, the positive and negative electrodes of the light-emitting chip 104 each need to be connected to a second conductive structure, in this case, the laser device includes two second conductive structures, the two second conductive structures may be arranged on a side of the light-emitting chip 104 away from the target side wall B, or arranged on two sides of the light-emitting chip 104 in the y direction respectively.

In some embodiments, during the assembly process of the laser device 10 in which the packaging structure 103 is located, the second frame 1032 and the base plate 1031 may be fixed first, and then the light-emitting chip 104 may be mounted on the base plate 1031. After mounting the light-emitting chip 104 on the base plate 1031, the electrode of the light-emitting chip 104 may be connected to an end of the second conductive structure located in the second accommodating space 12, so that the light-emitting chip 104 is connected to the outside of the second accommodating space 12 enclosed by the packaging structure 103. Then, the second cover 1033 is fixed to a side of the second frame 1032 away from the base plate 1031 to seal the light-emitting chip 104. Thereafter, the packaging structure 103 mounted with the light-emitting chip 104 may be fixed on the substrate 101 as a whole, and an end of the second conductive structure located outside the second accommodating space 12 is connected to an end of the first conductive structure located in the first accommodating space 11, thereby enabling power supply to the light-emitting chip 104.

Afterwards, power is supplied to the light-emitting chip 104 to light up the light-emitting chip 104, and the mounting position of the component that the laser beams need to pass through is adjusted according to the irradiation of the laser beams emitted by the light-emitting chip 104, and then the component is mounted after determining a suitable mounting position. For example, for mounting the wavelength conversion component 105, a target may be firstly set at a position where the wavelength conversion component 105 is required to be set, and the position of the target may be adjusted according to the irradiation of the laser beams emitted by the light-emitting chip 104 on the target. When the irradiation condition of the laser beams on the target is made to meet the required irradiation condition on the wavelength conversion component 105, the position of the target is determined as the mounting position of the wavelength conversion component 105, and then the target is removed and the wavelength conversion component 105 is set at the position.

Some embodiments of the present disclosure are mainly described by considering an example in which the light-emitting chip 104 needs to be provided on the heat sink 107. In some embodiments, in a case where the packaging structure 103 has a base plate 1031 and the material of the base plate 1031 is ceramic, the light-emitting chip 104 may also be directly disposed on the base plate 1031 without providing the heat sink 107.

In some embodiments, referring to FIG. 4, the difference from the laser device in FIG. 1 is that the second accommodating space 12 has a different forming manner. The packaging structure 103 includes a second frame 1032 and a second cover 1033. The end surface of the second frame 1032 proximate to the substrate 101 is fixed to the substrate 101. The substrate 101, the second frame 1032 and the second cover 1033 enclose the second accommodating space 12 for sealing the light-emitting chip 104.

In some embodiments, in the laser device 10 where the packaging structure 103 shown in FIG. 4 is located, the second conductive structure may be provided in the second frame 1032, and an end of the second conductive structure located in the enclosing region of the second frame 1032 is connected to the light-emitting chip 104, and another end located outside the enclosing region is connected to the first conductive structure.

Referring to FIG. 23, the second conductive structures J in the packaging structure 103 are located on two sides of the light-emitting chip 104 in the y direction respectively. For example, the upper surface of the light-emitting chip 104 may be used as a cathode, and the upper surface of the heat sink 107 may be used as an anode. Here, the upper surface refers to a surface of the light-emitting chip 104 or the heat sink 107 in the z direction.

In some embodiments, the packaging structure 103 may cover a portion of the region in the annular plate 1021, an end of the first conductive structure in the annular plate 1021 is located in the enclosed space of the packaging structure 103, and the light-emitting chip 104 may be directly connected to the first conductive structure to connect to an external circuit.

During the assembly process of the laser device 10 in which the packaging structure 103 shown in FIG. 4 is located, the light-emitting chip 104 may be mounted on the substrate 101 first, and the electrode of the light-emitting chip 104 may be electrically connected to the second conductive structure or the first conductive structure. Then, an adhesive (e.g., silver glue or other glue) is set around the light-emitting chip 104, and the second frame 1032 is fixed on the substrate 101 through the adhesive and encloses the light-emitting chip 104, after which the second cover 1033 is fixed on the second frame 1032 to seal the light-emitting chip 104.

In some embodiments, referring to FIG. 5, the packaging structure 103, the substrate 101, and the first frame 102 together form the second accommodating space 12 for placing the light-emitting chip 104. The packaging structure 103 may be fixed to the three first side walls 1022 in the first frame 102 to form the second accommodating space 12 together.

Referring to FIG. 5, the light-emitting chip 104 is located on the substrate 101. The packaging structure 103 is L-shaped and includes the target side wall B and the second cover 1033. An end of the target side wall B proximate to the substrate 101 (e.g., an end in the z direction) is fixed to the substrate 101, and another end of the target side wall B away from the substrate 101 is connected to the second cover 1033. The other edges of the packaging structure 103 are fixed to the corresponding first side walls 1022 of the first frame 102 respectively.

Referring to FIG. 6, a first side wall 1022 away from the wavelength conversion component 105 has a sealing step T protruding toward the first accommodating space 11. The second cover 1033 of the packaging structure 103 is fixed to the sealing step T. For example, a region of the surface of the second cover 1033 proximate to the substrate 101 which is away from the target side wall B is fixed to a surface of the sealing step T away from the substrate 101. The sealing step T may be in a shape of a strip, and two ends of the sealing step T in the y direction are in contact with the two first side walls 1022 respectively.

In some embodiments, the sealing step T is located at an end of the second side wall 10321 proximate to the annular plate 1021, and the bottom of the sealing step T is fixed to the annular plate 1021. Alternatively, there may be a gap between the sealing step T and the annular plate 1021.

In some embodiments, the target side wall B and the second cover 1033 may be a one-piece member, and the target side wall B and the second cover 1033 may be made of the same material.

It should be noted that the packaging structure 103 may be formed by means of a molding process. For example, the packaging structure 103 may be fixed to the substrate 101 and the first frame 102 by means of bonding (e.g., ultraviolet curing glue or thermosetting glue).

During the assembly process of the laser device 10 in which the packaging structure 103 shown in FIG. 6 is located, the light-emitting chip 104 is directly connected to the external circuit through the first conductive structure in the annular plate 1021 to achieve current transmission to the light-emitting chip 104.

In some embodiments, the laser device 10 further includes a welding platform, the welding platform may be located, together with the light-emitting chip 104, in the second accommodating space 12 formed by the packaging structure 103. The soldering platform is located between the light-emitting chip 104 and the sealing step T. The soldering platform is electrically connected to the first conductive structure, and the soldering platform is configured to assist the light-emitting chip 104 in electrically connecting to the first conductive structure.

It should be noted that the electrodes of the light-emitting chip 104 may be connected to the welding platform through wires, and then electrically connected to the first conductive structure through the welding platform. In some embodiments, the second accommodating space 12 formed by the packaging structure 103 of the laser device 10 may accommodate the plurality of light-emitting chips 104. Laser beams emitted by the plurality of light-emitting chips 104 may be directed toward the same wavelength conversion component 105. In this way, the fluorescence emission efficiency of the laser device 10 may be improved.

For example, laser beams emitted by the plurality of light-emitting chips 104 are directed toward the same region in the wavelength conversion component 105, thereby exciting the region to emit fluorescence. In this case, the light-emitting directions of the plurality of light-emitting chips 104 may intersect with each other and intersect at the wavelength conversion component 105.

For another example, the laser beams emitted by the plurality of light-emitting chips 104 may be directed toward different regions in the wavelength conversion component 105 respectively, and the laser beams emitted by each light-emitting chip 104 excite the corresponding region to emit fluorescence. The plurality of light-emitting chips 104 may be arranged in a row, and the light-emitting directions of the plurality of light-emitting chips 104 are parallel to each other.

In some embodiments, the laser device 10 may include a plurality of packaging structure 103. One or more light-emitting chips 104 are disposed in the second accommodating space 12 enclosed by each packaging structure 103. The one or more light-emitting chips 104 are configured to emit laser beams toward the wavelength conversion component 105. The laser beams emitted by the one or more light-emitting chips 104 are directed toward the same region in the wavelength conversion component 105. Alternatively, the laser beams emitted by the one or more light-emitting chips 104 are directed toward the central region of the wavelength conversion component 105. Alternatively, the laser beams emitted by the one or more light-emitting chips 104 are directed toward the entire region in the wavelength conversion component 105. In this way, the consistency of the light spots of the laser beams emitted by each light-emitting chip 104 may be improved, and the fluorescence excitation effect on the wavelength conversion component 105 may be improved.

It should be noted that the arrangement positions of the plurality of packaging structures 103 in the first accommodating space 11 of the laser device 10 may be symmetrical about a target axis. The wavelength conversion component 105 is in a shape of a sheet or plate, and the target axis is a straight line passing through the center of the wavelength conversion component 105 and parallel to the substrate 101. The plurality of packaging structures 103 are symmetrically arranged with respect to the target axis, and laser beams emitted by the plurality of packaging structures 103 are irradiated onto the wavelength conversion component 105. The energy irradiated by the laser beams at each position of the wavelength conversion component 105 is relatively uniform. In this way, it is conducive to improving the uniformity of the energy of laser beams irradiation received at each position on the wavelength conversion component 105, thereby ensuring the fluorescence excitation effect of the wavelength conversion component 105.

In some embodiments, in a case where the wavelength conversion component 105 is disposed perpendicular to the substrate 101, for example, the thickness direction of the wavelength conversion component 105 is parallel to the surface of the substrate 101, the target axis is the central axis of the wavelength conversion component 105.

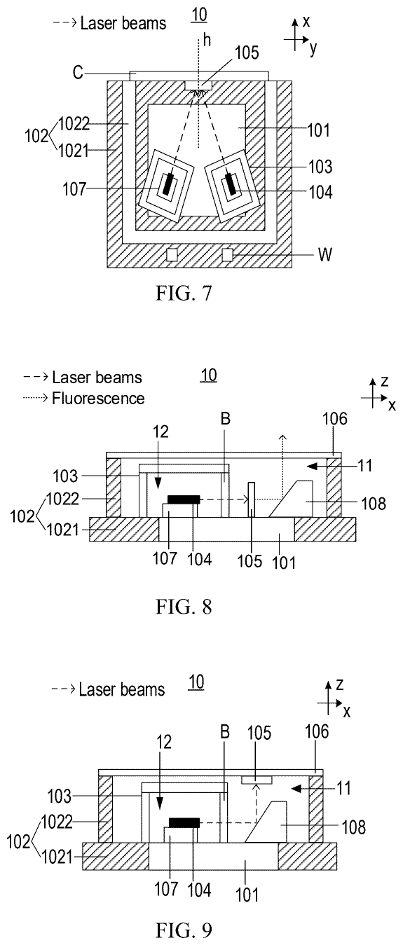

In some embodiments, referring to FIG. 7, the laser device 10 includes two packaging structures 103 and two light-emitting chips 104. The two packaging structures 103 are disposed obliquely on the substrate 101, and the disposition positions of the two packaging structures 103 are symmetrical about the target axis h. For example, the wavelength conversion component 105 is located on a light-transmissive first side wall 1022 of the first frame 102, and the target axis h is the central axis of the wavelength conversion component 105.

It should be noted that the laser device 10 may have multiple light-emitting manners.

In some embodiments, the fluorescence may be emitted from a side surface of the laser device 10, where the side surface is also the side where a first side wall 1022 of the first frame 102 is located. Alternatively, the fluorescent beams may be emitted from the top of the laser device 10, that is, the fluorescence is emitted from the first cover 106.

Due to different light emission manners, the structure of the first frame 102 in the laser device 10 will be different from each other to some extent, and the arrangement position and arrangement method of the wavelength conversion component 105 will also be different. The following mainly describes by considering an example in which the first frame 102 is in a shape of a square frame with four first side walls 1022.

In some embodiments, referring to FIG. 4 and FIG. 7, a first side wall of the first frame 102 located on the light exit side of the light-emitting chip 104 is provided with an opening K, and the laser device further includes a light-transmitting layer C, and the opening K is covered by the light-transmitting layer C. The laser beams exited from the packaging structure 103 is directed toward the light-transmitting layer C, and the light-transmitting layer C is configured to transmit the received laser beams. The wavelength conversion component 105 is located between the packaging structure 103 and the light-transmitting layer C. The first cover 106 may be made of a light-transmitting material or an opaque material (e.g., metal or ceramic).

In some embodiments, the wavelength conversion component 105 is disposed on the light-transmitting layer. For example, the wavelength conversion component 105 may be attached to a surface of the light-transmitting layer C proximate to the packaging structure 103. In this way, the laser beams exited from the packaging structure 103 may excite the wavelength conversion component 105 to emit fluorescence, and the fluorescence may directly pass through the light-transmitting layer C and exit from the laser device 10.

In some embodiments, the material of the light-transmitting layer C may be a light-transmitting material with good light-transmitting performance (e.g., sapphire). The wavelength conversion component 105 generates heat when excited to emit fluorescence. The light-transmitting layer C may assist the heat generated by the wavelength conversion component 105 to be dissipated quickly, thereby facilitating improving the fluorescence excitation effect of the wavelength conversion component 105.

In some embodiments, the wavelength conversion component 105 may also be fixed on the substrate 101 and spaced apart from the packaging structure 103 and the light-transmitting layer C.

The divergence angle of the fluorescence emitted by the wavelength conversion component 105 when excited is relatively large. In the manner in which the wavelength conversion component 105 is disposed on the light-transmitting layer C, the wavelength conversion component 105 is located at the rearmost end of the light path in the laser device 10. In this way, the light spot formed by the fluorescence emitted by the laser device 10 may be reduced, and the energy of the fluorescence may be concentrated. In addition, in this manner, the thickness of the wavelength conversion component 105 may be relatively small, and there is no need to reserve a position for the wavelength conversion component 105 in the first accommodating space 11, which is conducive to the miniaturized design of the laser device 10. In addition, there is no need to additionally provide a structure for fixing the wavelength conversion component 105, thereby simplifying the fixing manner of the wavelength conversion component 105.

In some embodiments, the size of the wavelength conversion component 105 may be less than the size of the light-transmitting layer C. For example, the wavelength conversion component 105 and the light-transmitting layer C each may be in a shape of a rectangle, and the area of the wavelength conversion component 105 may be less than the area of the light-transmitting layer C. In this way, the laser beams may be irradiated onto the smaller wavelength conversion component 105, which is conducive to improving the fluorescence excitation effect of the wavelength conversion component 105 and saving costs.

Since certain losses are inevitable in the process of light passing through any component, the laser device 10 in some embodiments of the present disclosure facilitates improving the light exit efficiency of the laser device 10 by reducing the components through which the laser beams or fluorescence passes.

In some embodiments, referring to FIG. 8, the laser device 10 further includes a reflective component 108 (e.g., reflecting prism). The reflective component 108 is located in the first accommodating space 11 enclosed by the substrate 101 and the first frame 102. The reflective component 108 is disposed on the light exit side of the light-emitting chip 104 and is provided away from the target side wall B. The wavelength conversion component 105 is located between the target side wall B and the reflective component 108. Alternatively, the wavelength conversion component 105 is located between the reflective component 108 and the first cover 106. The reflective component 108 is fixed to at least one of the substrate 101 and the first frame 102.

For example, the first cover 106 may be made of hard glass (e.g., K9 glass or sapphire glass). The laser beams or fluorescent beams reflected by the reflective component 108 are directed toward the first cover 106 and transmitted through the first cover 106. The first cover 106 may be fixed to the surface of the first frame 102 away from the substrate 101 by means of welding or bonding. If eutectic welding is used for fixing, solder may be pre-plated on the edge of the first cover 106, and then the first cover 106 is placed on the surface of the first frame 102 away from the substrate 101, and the solder is heated to melt the solder, thereby achieving welding of the first cover 106 and the first frame 102.

Referring to FIGS. 8 and 9, in some embodiments, the laser beams exited from the packaging structure 103 are directed toward the reflective component 108, and the reflective component 108 is configured to reflect the received light (laser beams or fluorescent beams) toward the first cover 106 along a direction away from the substrate 101 (e.g., z direction).

It should be noted that the reflective component 108 may be in a shape of a prism, and the reflective component 108 has an inclined surface facing the light-emitting chip 104, and the inclined surface serves as a light reflecting surface, and a reflective film may be coated on the inclined surface. The reflective film may be a reflective film for light of all wavelengths. Alternatively, the reflective film may be a reflective film for received light. The substrate of the reflective component may be glass or silicon.

In some embodiments, referring to FIG. 8, the wavelength conversion component 105 is located between the target side wall B and the reflective component 108. The wavelength conversion component 105 is fixed on the substrate 101 and is spaced apart from the target side wall B and the reflective component 108. The wavelength conversion component 105 is in the shape of a sheet or a plate, and the thickness direction of the wavelength conversion component 105 is parallel to the surface of the substrate 101.

In some embodiments, referring to FIGS. 9 and 18, the wavelength conversion component 105 may also be fixed on the inclined surface of the reflective component 108. Alternatively, the wavelength conversion component 105 may be fixed on the surface of the target side wall B proximate to the reflective component 108. In a case where the wavelength conversion component 105 is fixed on the inclined surface of the reflective component 108, the size of the wavelength conversion component 105 may be less than the size of the inclined surface (e.g., the orthographic projection of the wavelength conversion component 105 on the inclined surface being located in the inclined surface), and the region covered by the wavelength conversion component 105 in the inclined surface may be coated with a reflective film.

Referring to FIG. 9, the wavelength conversion component 105 is located between the reflective component 108 and the first cover 106. The wavelength conversion component 105 is fixed to a surface of the first cover 106 proximate to the substrate 101. The first cover 106 may assist the wavelength conversion component 105 in dissipating heat.

It should be noted that the wavelength conversion component 105 may also be disposed on the light path of the laser beams reflected by the reflective component 108 through other fixing components and spaced apart from the reflective component 108 and the first cover 106. For example, the fixing component may clamp the wavelength conversion component 105 to fix the wavelength conversion component 105 and the reflective component 108 away from the surface of the substrate 101.

It should be noted that, during the process of mounting the reflective component 108 in the laser device 10, the mounting position of the reflective component 108 may be actively adjusted to determine a suitable mounting position. For example, the mounting position of the reflective component 108 may be determined based on whether the shape and size of the light spot formed on the reflective component 108 by the laser beams emitted by the light-emitting chip 104 meets the requirements.

In order to ensure the fluorescence excitation effect on the wavelength conversion component 105, it is necessary to make the energy distribution of the laser beams on the wavelength conversion component 105 concentrated, and the laser beams emitted by the light-emitting chip 104 have a certain divergence angle, so a first collimation component may also be provided in the laser device 10 to collimate the laser beams. Collimating the laser beams mean limiting the divergence angle of the laser beams so that the laser beams are proximate to parallel light. In this way, the energy of the laser beams may be more concentrated, and the light spot formed by the laser beams may be reduced, which is convenient for the transmission of the laser beams.

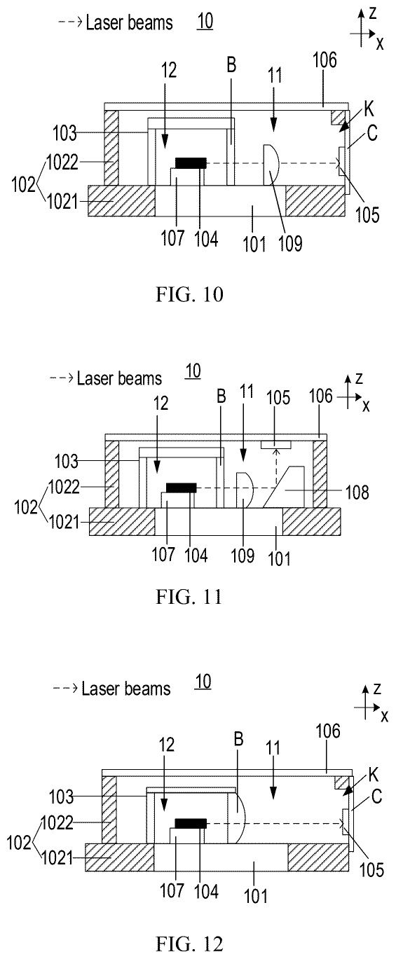

In some embodiments, referring to FIGS. 10 and 11, the laser device 10 further includes a first collimating lens (e.g., a collimating lens 109). The collimating lens 109 is located in the first accommodating space 11 enclosed by the substrate 101 and the first frame 102. The collimating lens 109 is disposed on a side of the target side wall B away from the light-emitting chip 104. The laser beams exited from the packaging structure 103 are directed toward the collimating lens 109. The collimating lens 109 is configured to collimate the received laser beams and then direct the collimated laser beams toward the wavelength conversion component 105. The laser beams collimated by the collimating lens 109 are directed toward the reflective component 108 and then directed toward the wavelength conversion component 105 after being reflected by the reflective component 108. In this way, the divergence angle of the laser beams may be reduced through the first collimating component, so that the laser beams are proximate to parallel light, the energy of the laser beams is concentrated, the light spot formed by the laser beams is reduced, and the transmission of the laser beams is facilitated.

In some embodiments, by designing the target side wall B of the packaging structure 103, a portion of the target side wall B may be configured as the first collimating component to collimate the laser beams after passing through the target side wall B. For example, referring to FIG. 12, a surface of the target side wall B away from the light-emitting chip 104 is configured as a convex curved surface. The laser beams emitted by the light-emitting chip 104 may be collimated after passing through the convex curved surface of the target side wall B.

In some embodiments, the surface of the target side wall B proximate to the light-emitting chip 104 may be a convex curved surface.

In some embodiments, the target side wall B of the packaging structure 103 may have a convex curved surface protruding toward the inside of the second accommodating space 12 enclosed by the packaging structure 103 or out of the second accommodating space 12, so that the received laser beams may be collimated and then exit out of the packaging structure 103. In this way, there is no need to provide the collimating lens, which may reduce the number of components and facilitate the miniaturization design of the laser device 10.

In some embodiments, the laser device 10 includes a plurality of light-emitting chips 104. The number of the collimating lenses 109 is the same as that of the light-emitting chips 104. Each light-emitting chip 104 corresponds to a collimating lens 109, and the laser beams emitted from each light-emitting chip 104 is collimated by the corresponding collimating lens 109.

It should be noted that, during the process of mounting the collimating lens 109, the mounting position of the collimating lens 109 may be actively adjusted. For example, the mounting position of the collimating lens 109 may be determined based on whether the shape and size of the light spot formed by the laser beams emitted by the light-emitting chip 104 after passing through the collimating lens 109 meet the requirements. In this way, the shape and size of the light spot formed by the laser beams after collimation by the mounted collimating lens 109 may meet the requirements, thereby improving the light exit quality of the laser device 10.

Referring to FIG. 11, in the process of mounting the collimating lens 109 and the reflective component 108, first ensure that the light-emitting chip 104, the collimating lens 109 and the reflective component 108 are in the same straight line. Next, the position of the collimating lens 109 is adjusted so that the shape and size of the light spot formed on the reflective component 108 after the laser beams emitted by the light-emitting chip 104 pass through the collimating lens 109 substantially meet the requirements. After the position of the collimating lens 109 is determined, the position of the reflective component 108 may be adjusted to a certain extent to ensure that the shape and size of the light spot on the reflective component 108 after mounting meet the requirements, so that the laser beams reflected by the reflective component 108 also meet the requirements.

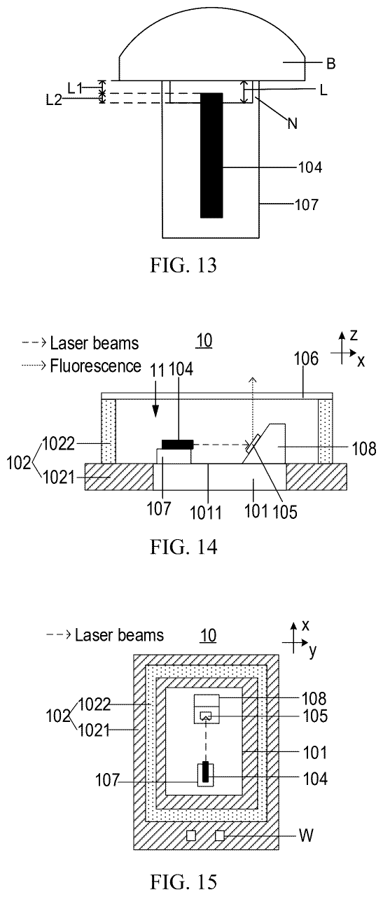

Referring to FIG. 13, one or more limiting bosses N may be provided at an end of the heat sink 107 proximate to the target side wall B. The limiting bosses N are located outside the setting region of the light-emitting chip 104 to avoid blocking the laser beams emitted by the light-emitting chip 104. For example, in a case where two limiting bosses N are disposed at the end of the heat sink 107 proximate to the target side wall B, the two limiting bosses N are located at two sides of the light-emitting chip 104 respectively. The distance L of each limiting boss N protrudes is equal to the sum of the distance L1 between the light-emitting chip 104 and the target side wall B and the distance L2 of the light-emitting chip 104 protruding from the heat sink 107. In this way, when mounting the heat sink 107, the limiting boss N may be directly against the target side wall B, thereby ensuring that the target side wall B has a good collimation effect on the laser beams.

In some embodiments, a converging lens may be further provided outside the first accommodating space 11 of the laser device 10 to converge the fluorescence emitted by the laser device 10.

In some embodiments, referring to FIGS. 14 and 15, the substrate 101 is fixed to the first frame 102, the light-emitting chip 104, the reflective component 108 and the wavelength conversion component 105 each are located on the substrate 101 and enclosed by the first frame 102. It should be noted that the first cover 106 is not illustrated in FIG. 15.

The enclosure described in the embodiments of the present disclosure may be a semi enclosure (e.g., partially surround) or a full enclosure.

For example, referring to FIG. 14, the first frame 102 fully encloses each component on the substrate 101. The substrate 101 and the first frame 102 enclose the first accommodating space 11. The substrate 101 is configured to form a bottom of the first accommodating space 11, and the first frame 102 forms a side wall of the first accommodating space 11. The light-emitting chip 104, the reflective component 108 and the wavelength conversion component 105 each are located in the first accommodating space 11. The reflective component 108 is spaced apart from one of the plurality of first side walls 1022 located at the light exit side of the light-emitting chip 104.

Referring to FIG. 15, the light-emitting chip 104 is located on the substrate 101, and the orthographic projection of the light-emitting chip 104 may be located on the substrate 101. In this way, the heat generated by the light-emitting chip 104 may be dissipated through the substrate 101.

Referring to FIGS. 14 and 15, the reflective component 108 is located at the light exit side of the light-emitting chip 104, the light-emitting chip 104 and the reflective component 108 are sequentially arranged along the light exit direction (e.g., x direction) of the light-emitting chip 104. The reflective component 108 may be in the shape of a prism, and the arrangement direction of the upper base and the lower base of the prism (i.e., the height direction, such as the opposite direction of the z direction) may be perpendicular to the light exit direction of the light-emitting chip 104.

In some embodiments, the side surface of the reflective component 108 proximate to the light-emitting chip 104 is an inclined surface, and the inclined surface faces the light-emitting chip 104 and a side away from the substrate 101. An angle between the inclined surface and the first surface 1011 of the substrate 101 is an acute angle, for example, the angle is 45 degrees. The inclined surface may serve as a reflective surface for light.

Referring to FIGS. 14 and 15, the wavelength conversion component 105 is located between the light-emitting chip 104 and the reflective component 108. For example, the wavelength conversion component 105 is located on the inclined surface of the reflective component 108. For example, the wavelength conversion component 105 is in the shape of a sheet or a plate and is attached to the inclined surface.

In some embodiments, the laser beams emitted by the light-emitting chip 104 are directed toward the wavelength conversion component 105. After the laser beams are directed toward the wavelength conversion component 105, the wavelength conversion component 105 may be excited to emit light with a wavelength different from that of the laser beams, so as to achieve wavelength conversion of the laser beams. In this way, it is conducive to improving the flexibility of the use of the laser device 10 and the application scenarios of the laser device 10 may be enriched.

It should be noted that wavelength conversion component 105 is excited to emit fluorescence that may be directed toward the first cover 106 and transmit through the first cover 106, so that the light exit of the laser device 10 may be realized. The surface of the wavelength conversion component 105 proximate to the inclined surface is a reflective surface.

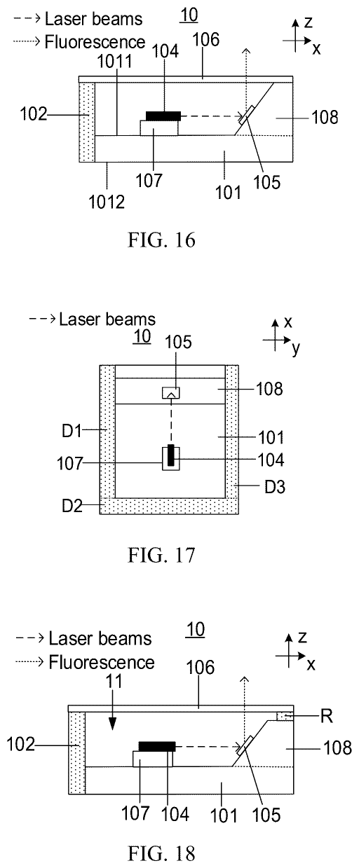

Referring to FIGS. 14 and 16, the reflective surface is configured to reflect the fluorescent beams in a direction away from the substrate 101 (e.g., z direction) and then direct the fluorescent beams toward the first cover 106.

In some embodiments, a reflective film may be coated on the inclined surface to achieve the light reflecting effect of the inclined surface.

It should be noted that the reflective film may be a reflective film for light of all wavelengths. Alternatively, the reflective film may be a reflective film for fluorescence.

In some embodiments, the reflective film may cover the entire region of the inclined surface or may cover a region of the inclined surface where the wavelength conversion component 105 is disposed.

For example, the area of the wavelength conversion component 105 may be less than the area of the inclined surface of the reflective component 108. In this way, the laser beams are irradiated onto the smaller wavelength conversion component 105, which is conducive to improving the fluorescence excitation effect of the wavelength conversion component 105 and avoiding the waste of materials.

In some embodiments, referring to FIGS. 16 and 17, the first frame 102 does not include the annular plate 1021, the first frame 102 includes the plurality of first side walls 1022. The first frame 102 may be located on the substrate 101, and an end surface of the first frame 102 in the axial direction (e.g., z direction) is fixed to the first surface 1011 of the substrate 101. This manner is equivalent to setting the annular plate 1021 in FIG. 14 as the substrate 101 as well.

For example, the plurality of first side walls 1022 in the first frame 102 may directly enclose the substrate 101, and the inner wall surface of each first side wall 1022 is fixed to the outer side surface of the substrate 101.

It should be noted that the reflective component 108 and the substrate 101 may be independent of each other, and the reflective component 108 needs to be mounted on the substrate 101 when assembling the laser device 10.

In some embodiments, referring to FIGS. 16 and 17, the substrate 101 and the reflective component 108 may be a one-piece member. The reflective component 108 is located on the first surface 1011 of the substrate 101 and at the edge of the light exit side of the light-emitting chip 104. The substrate 101 may be in a shape of a rectangle, and the substrate 101 has four edges. The reflective component 108 may be located at the edge of the four edges located on the light exit side of the light-emitting chip 104.

In some embodiments, referring to FIG. 17, the reflective component 108 may be in a shape of a strip, and the length of the reflective component 108 in the y direction may be equal to the length of the edge. The side surface of the reflective component 108 away from the light-emitting chip 104 is flush with the side surface of the substrate 101 away from the light-emitting chip 104.

In some embodiments, referring to FIG. 16, the material of the reflective component 108 is the same as that of the substrate 101. The wavelength conversion component 105 is disposed on the inclined surface of the reflective component 108. The wavelength conversion component 105 generates heat when excited to emit fluorescence, and the heat may be conducted to the substrate 101 through the reflective component 108, so that the heat is dissipated quickly, which is conducive to ensuring the fluorescence excitation effect of the wavelength conversion component 105.

It should be noted that there may be no fixed interface between the reflective component 108 and the substrate 101, and the heat transfer between the reflective component 108 and the substrate 101 will not be hindered by the interface, thereby increasing the rate of heat dissipation.

In some embodiments, referring to FIGS. 16 and 17, the first frame 102, the substrate 101 and the reflective component 108 enclose the first accommodating space 11. The first frame 102 may partially surround the light-emitting chip 104, the reflective component 108 and the wavelength conversion component 105. Referring to FIG. 17, the first frame 102 includes a first first side wall (e.g., D1), a second first side wall (e.g., D2) and a third first side wall (e.g., D3) connected in sequence. The second first side wall is opposite to the reflective component 108, and the first first side wall and the third first side wall are fixed to two surfaces of the reflective component 108 located on two opposite sides of the inclined surface respectively. For example, the first first side wall and the third first side wall are fixed to two surfaces of the reflective component 108 opposite to each other in the y direction, respectively.

For example, ends of the first first side wall and the third first side wall away from the second first side wall are fixed to the two side surfaces. Alternatively, partial regions of the inner wall surfaces of the first first side wall and the third first side wall away from the second first side wall are fixed to the two side surfaces. Here, the inner wall surface refers to a surface of the first side wall proximate to the first accommodating space 11.

It should be noted that the inner wall surfaces of the first first side wall, the second first side wall and the third first side wall may also be fixed to the three side surfaces of the substrate 101 respectively. Partial edge region of the first cover 106 may be fixed to the surfaces of the first first side wall, the second first side wall and the third first side wall. Partial edge region of the first cover 106 is fixed to the surface of the reflective component 108 away from the substrate 101.

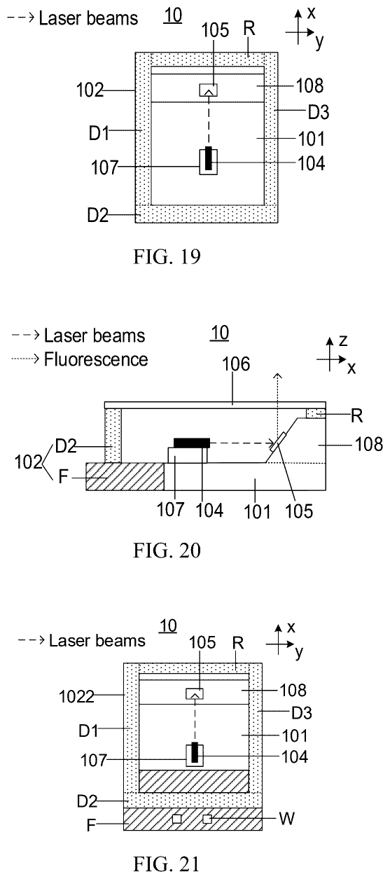

Referring to FIGS. 18 and 19, in some embodiments, the laser device 10 further includes a first connecting portion (e.g., a sealing block R). Two ends of the sealing block R are connected to the first first side wall and the third first side wall respectively, and the surface of the sealing block R proximate to the reflective component 108 (e.g., the surface in the opposite direction of the z direction) is fixed to the surface of the reflective component 108 away from the substrate 101.

It should be noted that the surface of the sealing block R away from the reflective component 108 (e.g., the surface in the z direction), and the surfaces of the first first side wall, the second first side wall and the third first side wall away from the substrate 101 form a flat annular surface, so that the sealing effect of the contact region between the annular surface and the first cover 106 may be ensured.

In some embodiments, referring to FIG. 20 and FIG. 21, the first frame 102 includes a second connecting portion (e.g., a plate-shaped portion F), and the second first side wall is located on the plate-shaped portion F. The bottom surfaces of the first first side wall and the third first side wall may be flush with the bottom surface of the plate-shaped portion F. A side surface of the substrate 101 proximate to the second first side wall is fixed to the side surface of the plate-shaped portion F, and the two side surfaces of the substrate 101 connected to the side surface are fixed to the first first side wall and the third first side wall respectively. For example, based on FIGS. 16 and 17, the first frame 102 may further include a plate-shaped portion F and the like.

A conductive structure W connecting the inside and outside of the enclosed region of the first frame 102 may be provided in the plate-shaped portion F, and the light-emitting chip 104 is electrically connected to an end of the conductive structure W located in the enclosed region of the first frame 102. FIG. 21 illustrates the exposed portion of the conductive structure W that is located outside the enclosed region of the first frame 102, which may facilitate the circuit connection of the light-emitting chip 104. With respect to the circuit structure W, reference may be made to the above-mentioned relevant description to the circuit structure in the annular plate 1021, and details will not be repeated herein.

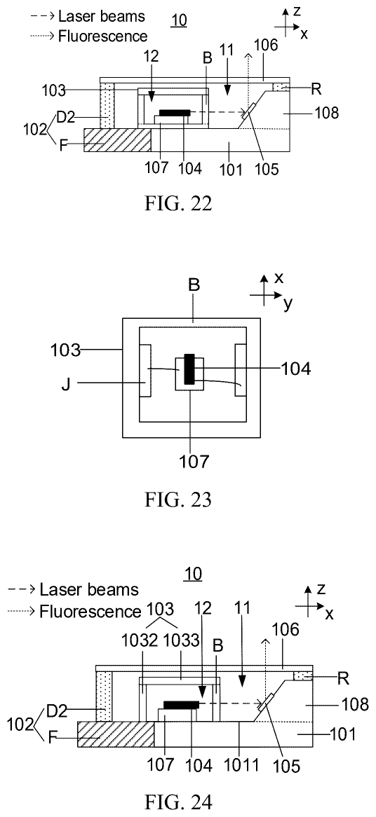

Based on any of the above-mentioned laser devices 10, the structure and function of the packaging structure 103 in the laser device 10 shown in FIG. 22 are similar to those of the packaging structure shown in FIGS. 1 and 3, and details will not be repeated herein.

In some embodiments, the packaging structure 103 may not include the base plate 1031. Referring to FIG. 24, the packaging structure 103 includes a second frame 1032 and a second cover 1033. The second frame 1032 is fixed to the first surface 1011. The substrate 101, the second frame 1032 and the second cover 1033 enclose the second accommodating space 12 for sealing the light-emitting chip 104.

It should be noted that there is no need for a base plate 1031 to be provided between the light-emitting chip 104 and the substrate 101, and heat generated by the light-emitting chip 104 may be directly transmitted to the substrate 101 and then dissipated to the outside through the substrate 101. In this way, the heat dissipation path may be shortened and the heat dissipation effect of the laser device 10 may be improved.

In the laser device 10 where the packaging structure 103 is located, a second conductive structure may be provided in the second frame 1032, an end of the second conductive structure located within the enclosed region of the second frame 1032 is connected to the light-emitting chip 104, and another end located outside the enclosed region is connected to the first conductive structure.

Alternatively, the packaging structure 103 may cover a partial region of the plate-shaped portion F of the first frame 102, an end of the first conductive structure in the plate-shaped portion F is located in the enclosed space of the packaging structure 103, and the light-emitting chip 104 may be directly connected to the first conductive structure to communicate with an external circuit.

The assembly process of the laser device 10 in which the packaging structure 103 shown in FIG. 24 is located is similar to that described above and details will not be repeated herein.

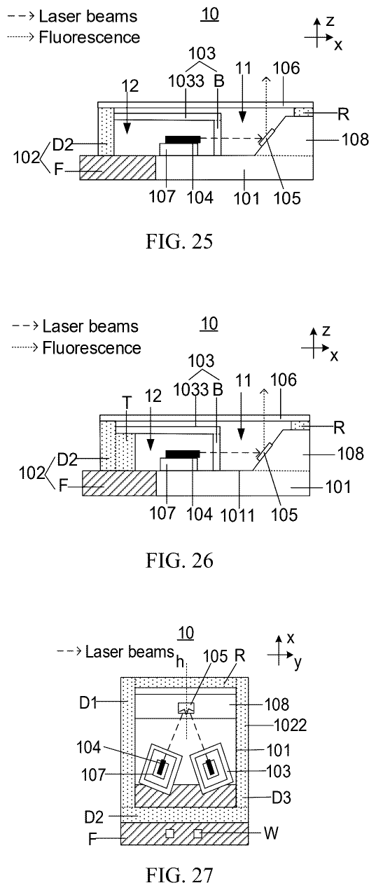

In some embodiments, referring to FIG. 25, the first light-emitting chip 104 is located on the substrate 101. The packaging structure 103 in FIG. 25 is similar to that in FIG. 4, and details will not be repeated herein.

In some embodiments, referring to FIG. 26, a first side wall 1022 of the first frame 102 away from the wavelength conversion component 105 has a sealing step T protruding inwardly toward the second accommodating space 12. The second cover 1033 is fixed to the sealing step T.

For example, a region of the second cover 1033 proximate to a side of the first surface 1011 and away from the target side wall B is fixed to a surface of the sealing step T away from the substrate 101. The sealing step T may be in a shape of a strip, two ends of the sealing step T, in the y direction, are in contact with the two first side walls 1022 respectively.

In some embodiments, the sealing step T is located at an end of the corresponding first side wall 1022 proximate to the plate-shaped portion F, and the bottom of the sealing step T is fixed to the plate-shaped portion F. Alternatively, there may be a gap between the sealing step T and the plate-shaped portion F, that is, the two are spaced apart by a predetermined distance.

In some embodiments, referring to FIG. 25 and FIG. 26, the target side wall B and the second cover 1033 may be a one-piece member, and the target side wall B and the second cover 1033 may be made of the same material. For example, the material may include a light-transmitting material such as glass or sapphire.

In the laser device 10 where the packaging structure 103 is located, the light-emitting chip 104 is directly connected to the external circuit through the first conductive structure in the plate-shaped portion F to achieve current transmission to the light-emitting chip 104.

In some embodiments, referring to FIG. 27, the laser device 10 includes two packaging structures 103 and two light-emitting chips 104. The two packaging structures 103 are disposed obliquely on the substrate 101, and the disposition positions of the two packaging structures 103 are symmetrical about the target axis h.

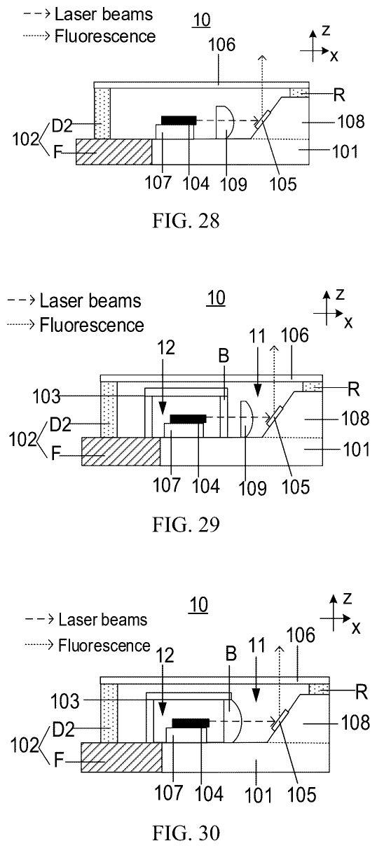

In some embodiments, referring to FIG. 28, the collimating lens 109 is located between the light-emitting chip 104 and the wavelength conversion component 105. The laser beams emitted by the light-emitting chip 104 are directed toward the collimating lens 109. The collimating lens 109 is configured to collimate the received laser beams and then direct the laser beams toward the wavelength conversion component 105. The laser beams directed toward the wavelength conversion component 105 are the collimated laser beams.

In some embodiments, referring to FIG. 29, the collimating lens 109 is disposed on the substrate 101 and located on a side of the target side wall B away from the light-emitting chip 104. In this way, the laser beams exited from the packaging structure 103 may be directed toward the collimating lens 109.

It should be noted that the process of mounting the collimating lens 109 in the laser device 10 shown in FIG. 29 and the process of mounting the reflective component 108 are similar to those in FIG. 11, and details will not be repeated herein.

The packaging structure 103 in FIG. 30 is similar to the packaging structure in FIG. 12, and details will not be repeated herein.

It should be noted that, similar to FIG. 13, in the laser device 10 shown in FIG. 30, one or more limiting bosses N may be provided at an end of the heat sink 107 proximate to the target side wall B, and the limiting bosses N are located outside the setting region of the light-emitting chip 104 to avoid blocking the laser beams emitted by the light-emitting chip 104.

With regard to the relative positional relationship between the limiting boss N, the light-emitting chip 104 and the target side wall, reference may be made to the above-mentioned related contents, and details will not be repeated herein.

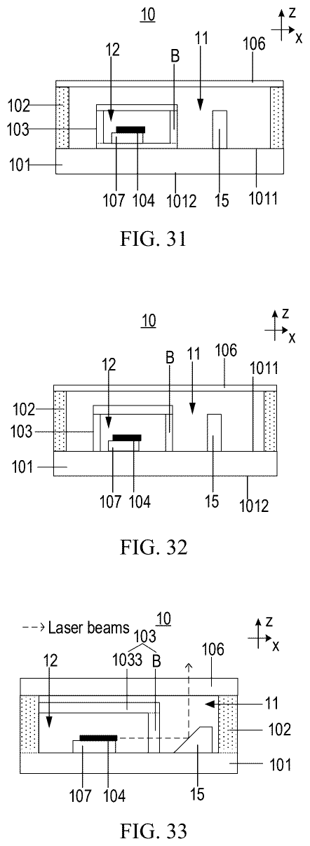

It should be noted that the laser devices shown in FIGS. 31 to 49 do not include the wavelength conversion component 105.

In some embodiments, referring to FIG. 31, the first accommodating space 11 is defined between the substrate 101 and the first frame 102. The packaging structure 103, the light-emitting chip 104 and a target optical element 15 each are located in the first accommodating space 11.

The first cover 106 is fixed to a side of the first frame 102 away from the substrate 101, and the first cover 106 is configured to seal the first accommodating space 11.

In some embodiments, the first frame 102 is located on the first surface 1011, and an end surface of the first frame 102 is fixedly connected to the first surface 1011. The first frame 102 may be substantially in a shape of a square frame, and the first frame 102 includes four first side walls connected in sequence.

The packaging structure 103 is configured to seal the light-emitting chip 104, and the packaging structure 103 may define the second accommodating space 12 independently. It should be noted that the packaging structure 103 and the encapsulation process in the laser device 10 shown in FIG. 31 are similar to the packaging structure 103 and the encapsulation process shown in FIG. 1, and details will not be repeated herein.

In some embodiments, the packaging structure 103 includes the light-transmissive target side wall B located on the light exit side of the light-emitting chip 104. The light-emitting chip 104 is configured to emit laser beams toward the target side wall B, and the laser beams are directed toward the target optical element 15 through the target side wall B. The target optical element 15 is an element in the laser device 10 for adjusting the laser beams. The target optical element 15 is configured to direct the received laser beams out of the first accommodating space 11 to realize the light exit of the laser device 10.

In some embodiments, referring to FIG. 31, the substrate 101, the first frame 102, and the first cover 106 together constitute the encapsulation of the entire laser device 10. After the packaging structure 103 performs a primary encapsulation on the light-emitting chip 104, the first cover 106, the substrate 101 and the first frame 102 may perform a secondary encapsulation on the light-emitting chip 104, as well as an encapsulation on the packaging structure 103 and the target optical element 15.

When assembling the laser device 10, the light-emitting chip 104 may be performed a primary encapsulation in the first accommodating space 11 through the packaging structure 103, and then the target optical element 15 may be mounted on the substrate 101, and then the first cover 106 may be fixed on the side of the first frame 102 away from the substrate 101.

It should be noted that during the mounting process of the target optical element 15, the light-emitting chip 104 may be illuminated. Since the light-emitting chip 104 has been sealed by the packaging structure 103, lighting the light-emitting chip 104 will not cause damage to the light-emitting chip 104 from external pollutants, and the working reliability of the light-emitting chip 104 may still be guaranteed.

After the light-emitting chip 104 is turned on, the mounting position of the target optical element 15 may be adjusted based on the irradiation of the laser beams emitted by the light-emitting chip 104, that is, the target optical element 15 is actively adjusted. For example, the position of the target optical element 15 is adjusted according to the size and shape of the light spot formed by the laser beams on the target optical element 15, or the size and shape of the light spot formed at a specified position after the laser beams pass through the target optical element 15.

In this way, it may be ensured that the irradiation of the laser beams emitted by the light-emitting chip 104 on the target optical element 15 meets the requirements, and accordingly the laser beams exited after passing through the target optical element 15 also meets the requirements, there is no need to re-mount the target optical element 15 after encapsulation. Furthermore, it may be ensured that the beam quality of the laser beams emitted by the laser device 10 and the shape of the formed light spot meet the requirements, thereby ensuring the light exit effect of the laser device 10. It should be noted that the setting manner and encapsulation process of the light-emitting chip 104 and the heat sink 107 of the laser device 10 shown in FIG. 31 are similar to those of the light-emitting chip 104 and the heat sink 107 shown in FIG. 1, and details will not be repeated herein.

In some embodiments, the packaging structure 103 may further define the second accommodating space 12 together with other components. For example, referring to FIG. 32, the packaging structure 103 and the substrate 101 together define the second accommodating space 12. The packaging structure 103 and the encapsulation process in the laser device 10 shown in FIG. 32 are similar to the packaging structure 103 and the encapsulation process in FIG. 4, and details will not be repeated herein.

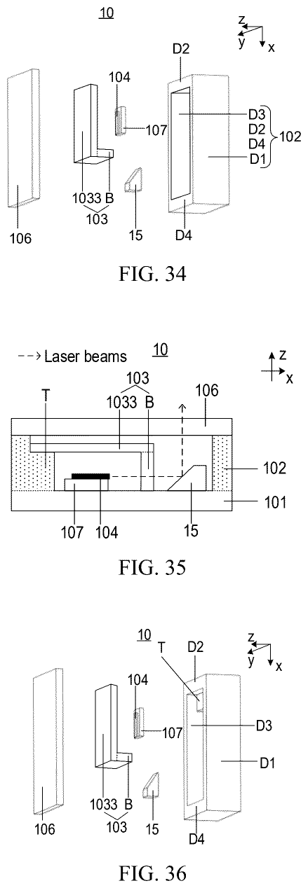

Referring to FIGS. 33 and 34, FIG. 34 is an exploded view of the laser device 10 shown in FIG. 33. In some embodiments, referring to FIG. 33, the packaging structure 103, the first frame 102 and the substrate 101 together define the second accommodating space 12. The packaging structure 103 and the encapsulation process in the laser device 10 shown in FIG. 33 are similar to the packaging structure 103 and the encapsulation process in FIG. 5, and details will not be repeated herein.

In some embodiments, as shown in FIG. 34, the first frame 102 includes four first side walls connected in sequence, and the four first side walls are a first first side wall D1, a second first side wall D2, a third first side wall D3 and a fourth first side wall D4 respectively. The second first side wall D2 and the fourth first side wall D4 are arranged in sequence along the x direction. The second first side wall D2 is located at a side of the light-emitting chip 104 away from the target optical element 15; the first first side wall D1 and the third first side wall D3 are arranged in sequence along the y direction, and the x direction is perpendicular to the y direction. An end surface of the second cover 1033 away from the target side wall B is fixed to the second first side wall D2, and two end surfaces of the second cover 1033 and the target side wall B in the y direction are fixed to the first first side wall D1 and the third first side wall D3 respectively. The sealed space where the light-emitting chip 104 is located is enclosed by the packaging structure 103, the first first side wall D1, the second first side wall D2, the third first side wall D3 and the substrate 101 (referring to FIG. 32).

In some embodiments, referring to FIGS. 35 and 36, FIG. 36 is an exploded view of the laser device shown in FIG. 35. The setting position and structure of the sealing step T and the packaging structure 103 of the laser device 10 shown in FIG. 35 are similar to those of the sealing step T and the packaging structure 103 in FIG. 6, and details will not be repeated herein.

It should be noted that the material of the substrate 101 or the first frame 102 provided with the conductive structure may be a high-temperature co-fired ceramic (HTCC) or a low-temperature co-fired ceramic (LTCC). The substrate 101 and the first frame 102 may be a one-piece member.

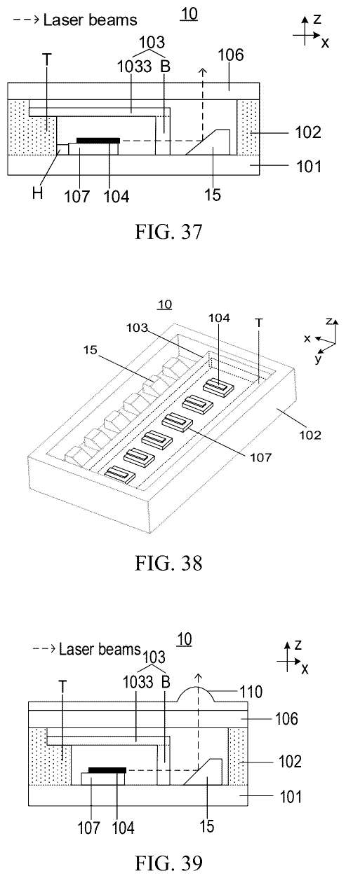

In some embodiments, referring to FIG. 37, the laser device in FIG. 37 is different from the laser device in FIG. 35 in that a welding table H is further provided in the second accommodating space 12 of the laser device 10 shown in FIG. 37. The position and connection manner of the welding table H of the laser device 10 shown in FIG. 37 are similar to those of the welding table in FIG. 6. The packaging structure 103 of the laser device 10 shown in FIG. 37 is similar to that in FIG. 6, and details will not be repeated herein.

In some embodiments, referring to FIG. 38, a plurality of light-emitting chips 104 arranged in a row along the y direction are provided in the second accommodating space formed by the packaging structure 103 of the laser device 10.

It should be noted that FIG. 38 considers an example in which six light-emitting chips 104 are provided in the second accommodating space. Accordingly, the laser device 10 includes six target optical elements 15 corresponding to the six light-emitting chips 104 respectively.

Some embodiments of the present disclosure mainly consider an example in which each laser device 10 includes one packaging structure 103. In some embodiments, the laser device 10 may also include a plurality of packaging structures 103, and the plurality of light-emitting chips 104 are located in a plurality of second accommodating spaces enclosed by the plurality of packaging structures 103 respectively.

Embodiments of laser device including a number of different light exit manners are described above. Under different light exit manners, the structure of the first frame 102 in the laser device 10 will be different to a certain extent, and accordingly, the target optical element 15 will also be different.

In some embodiments, target optical element 15 includes at least one of a reflective component or a collimating lens. For example, the target optical element 15 includes a reflecting prism. Alternatively, the target optical element 15 includes a reflecting prism and a collimating lens. Alternatively, the target optical element 15 includes a collimating lens.

In some embodiments, referring to FIG. 38, the target optical element 15 is a reflecting prism. The laser beams emitted by the light-emitted chip 104 are reflected by the corresponding reflecting prism and exited from the laser device 10. The function and installation process of the reflecting prism shown in FIG. 38 are similar to those of the reflective component 108 in FIG. 8 or FIG. 9, and details will not be repeated herein.

It should be noted that in this type of laser device 10, the structure and function of the first cover 106 are similar to those of the first cover 106 in FIG. 8, and details will not be repeated herein.

Referring to FIG. 39, in some embodiments, the laser device 10 includes a second collimating component (e.g., a convex curved surface 110). The convex curved surface provided on a side of the first cover 106 may constitute the second collimating component.

For example, the convex curved surface 110 is located on a side of the first cover 106 away from the substrate 101, and the laser beams reflected by the target optical element 15 is directed toward the convex curved surface 110 after passing through the first cover 106, so as to be collimated by the convex curved surface 110 and then exited from the laser device.

FIG. 39 illustrates the light emission of a light-emitting chip 104. It should be noted that in a case where the laser device 10 includes a plurality of light-emitting chips 104, the number of the convex curved surfaces 110 is the same as the number of the light-emitting chips 104 and the convex curved surfaces 110 and the light-emitting chips 104 are provided in correspondence with each other respectively.

Each light-emitting chip 104 corresponds to a convex curved surface 110, and the laser beams emitted by each light-emitting chip 104 are collimated by the corresponding convex curved surface 110. The plurality of convex curved surfaces 110 may be a one-piece member. The plurality of convex curved surfaces 110 are provided on a side of the first cover 106 away from the substrate 101. Each convex curved surface 110 may collimate the laser beams emitted by the corresponding light-emitting chip 104 and then exit the laser beams out of the laser device.

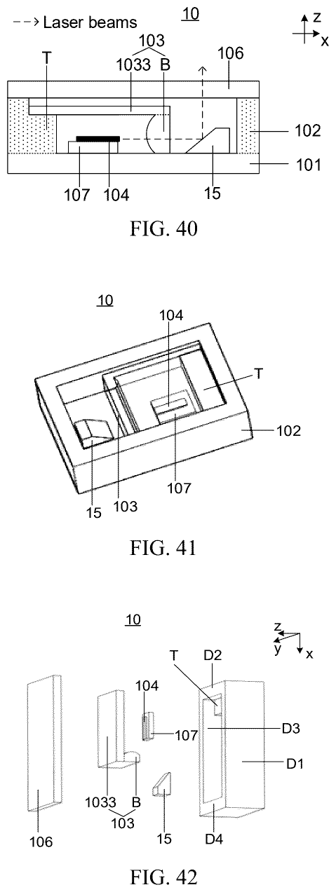

In some embodiments, referring to FIG. 40, based on the above-mentioned laser device 10, the target side wall B may be served as the second collimating component by changing the structure of the target side wall B of the packaging structure 103. In this way, the laser beams may be collimated during the process of passing through the target side wall B.

Referring to FIGS. 40 to 42, the surface of the target side wall B proximate to the light-emitting chip 104 may be a convex curved surface protruding toward the light-emitting chip 104. The laser beams emitted by the light-emitting chip 104 may be collimated after passing through the convex curved surface of the target side wall B.

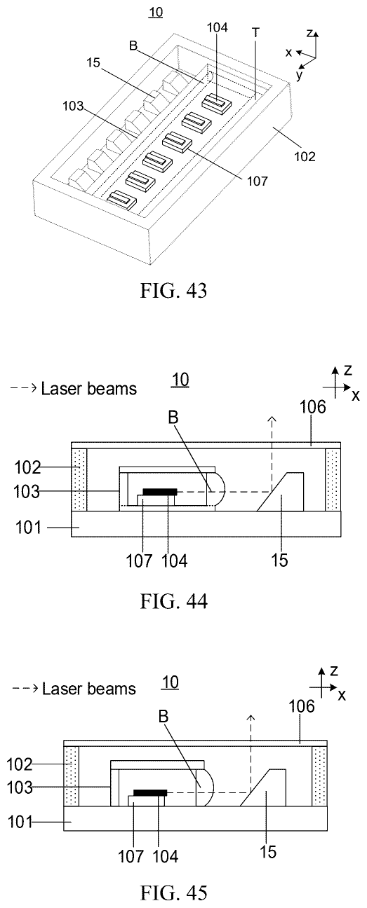

In some embodiments, referring to FIGS. 43 and 38, the difference between FIGS. 43 and 38 is that the surface of the target side wall B proximate to the light-emitting chip 104 may be a convex curved surface protruding toward the light-emitting chip 104, and the laser beams emitted by the plurality of light-emitting chips 104 may be collimated after passing through the convex curved surface of the target side wall B.

In some embodiments, the surface of the target side wall B away from the light-emitting chip 104 may be a convex curved surface protruding toward the side away from the light-emitting chip 104, in this way, the target side wall B may also collimate the laser beams.

For example, referring to FIG. 44, based on the laser device 10 shown in FIG. 31, the surface of the target side wall B of the packaging structure 103 away from the light-emitting chip 104 may be a convex curved surface. Referring to FIG. 45, based on the laser device 10 shown in FIG. 32, the surface of the target side wall B of the packaging structure 103 away from the light-emitting chip 104 may be a convex curved surface.

In this way, the laser beams may be collimated by the target side wall B, and there is no need to provide a second collimating component on the first cover 106, thereby reducing the height of the laser device 10, which is conducive to the miniaturization of the laser device 10.

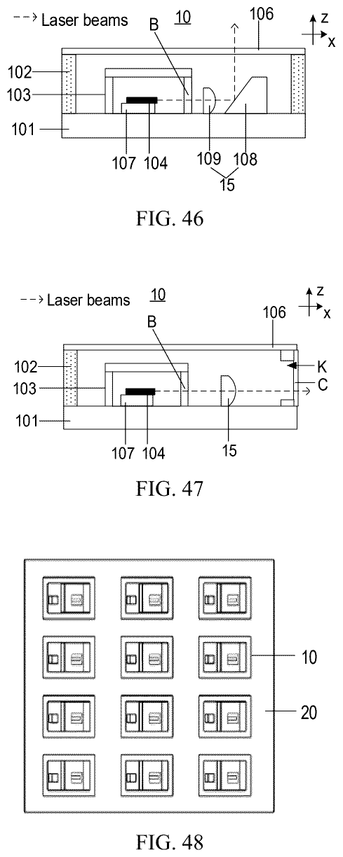

In some embodiments, referring to FIG. 46, the target optical element 15 includes a second collimating component (e.g., the collimating lens 109) and a reflective component 108 (e.g., the reflecting prism) located on the substrate 101, and the light-emitting chip 104, the collimating lens 109 and the reflective component 108 are arranged in sequence along the x direction.

The process of mounting the collimating lens 109 in the laser device 10 shown in FIG. 46 and the process of mounting the reflective component 108 are similar to those in FIG. 11, and details will not be repeated herein.

In some embodiments, referring to FIG. 47, the structure and function of the opening K of the laser device 10 shown in FIG. 47 are similar to those of the opening K in FIG. 4, and details will not be repeated herein.

Referring to FIG. 47, the target optical element 15 may be a second collimating component (e.g., a collimating lens). The laser beams emitted by the light-emitting chip 104 are directed toward the collimating lens after passing through the target side wall B of the packaging structure 103. After being collimated by the collimating lens, the laser beams are directed toward the light-transmitting layer C and then exited from the light-transmitting layer C.

During the process of mounting the collimating lens in the laser device 10, the mounting position of the collimating lens may be determined according to whether the shape and size of the light spot formed at the opening K of the first frame 102 after the laser beams emitted by the light-emitting chip 104 pass through the collimating lens meet the requirements. In this way, it may be ensured that the shape and size of the light spot formed by the laser beams after collimation by the mounted collimating lens meet the requirements, thereby improving the light exit quality of the laser device 10.

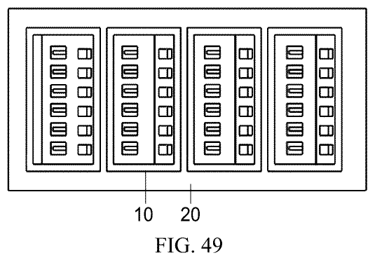

In some embodiments, if the optical power of a single laser device 10 cannot meet the requirements of the light source, a plurality of laser devices 10 may be used to form a laser assembly, and the laser assembly may be used as a light source so that the light source has higher optical power. Referring to FIG. 48, considering an example in which the laser device 10 in the laser assembly includes one light-emitting chip 104. Referring to FIG. 49, considering an example in which the laser device 10 in the laser assembly includes a plurality of light-emitting chips 104.

Referring to FIGS. 48 and 49, the laser assembly includes a carrier plate 20 and a plurality of laser devices 10 located on the carrier plate 20. The plurality of laser devices 10 may be arranged in a row on the carrier plate 20 (as shown in FIG. 49). Alternatively, the plurality of laser devices 10 may be arranged in multiple rows and columns (as shown in FIG. 48). The laser assembly adopts the encapsulation manner shown in FIG. 49, which may reduce the encapsulation volume to a certain extent and increase the number of encapsulated light-emitting chips.

Here, the material of the carrier plate 20 may include metal (e.g., copper plate). A circuit may be provided on the carrier plate 20, and the plurality of laser devices 10 may be connected through the circuit on the carrier plate 20. For example, an insulating material may be sprayed outside the region on the carrier plate where the laser device 10 is mounted, a circuit may be provided on the insulating material, and then insulating material may be sprayed on the circuit. The carrier plate 20 may also assist the laser device 10 in heat dissipation. The insulating material may also be a heat dissipation material.

For example, the plurality of laser devices 10 in the laser assembly may emit laser beams of the same color to meet the requirement of high power of the light source. Alternatively, different laser devices 10 may emit laser beams of different colors. For example, the laser assembly may include a red laser device, a green laser device and a blue laser device to emit red laser beams, green laser beams and blue laser beams respectively, ensuring that the laser assembly meets the requirements of a three-color (e.g., red, green and blue) light source.

The laser devices 10 in the laser assembly may be combined arbitrarily, and the assembly of the laser devices 10 is relatively flexible and may be adapted to the requirements of different usage scenarios.

A person skilled in the art will understand that the scope of disclosure in the present disclosure is not limited to specific embodiments discussed above, and may modify and substitute some elements of the embodiments without departing from the spirits of this application. The scope of this application is limited by the appended claims.

What is claimed is:

1. A laser device, comprising:
a substrate;
a first frame, the first frame being fixed to the substrate so as to define a first accommodating space;
at least one packaging structure, any one of the at least one packaging structure being located in the first accommodating space, and a second accommodating space being provided in the packaging structure;
at least one light-emitting chip, any one of the at least one light-emitting chip being located in the second accommodation space and configured to emit laser beams;
a target optical element, the target optical element being located in the first accommodating space;
a first cover, the first cover being fixed to a side of the first frame away from the substrate and configured to seal the first accommodating space;
wherein the packaging structure includes a target side wall, the target side wall is located on a light exit side of the light-emitting chip and is light-transmissive, the laser beams emitted by the light-emitting chip are directed toward the target optical element through the target side wall, and the target optical element is configured to exit received laser beams out of the first accommodating space.

2. The laser device according to claim 1, further comprising:
a wavelength conversion component, the wavelength conversion component being located in the first accommodating space;
wherein the wavelength conversion component is located in a transmission path of the laser beams transmitted from the packaging structure, and the wavelength conversion component is configured to emit fluorescence under excitation of the laser beams, and a color of the fluorescence is different from a color of the laser beams.

3. The laser device according to claim 2, wherein the first frame includes a plurality of first side walls connected in sequence, one of the plurality of first side walls located on the light exit side of the light-emitting chip is provided with an opening, and the laser device further comprises a light-transmitting layer, and the opening is covered by the light-transmitting layer;
wherein the laser beams exited from the packaging structure is directed toward the light-transmitting layer, and the light-transmitting layer is configured to transmit the received laser beams;
the wavelength conversion component is located between the packaging structure and the light-transmitting layer.

4. The laser device according to claim 3, wherein light-transmitting layer satisfies at least one of following:
the wavelength conversion component is connected to the light-transmitting layer; or
an area of the wavelength conversion component is less than an area of the light-transmitting layer.

5. The laser device according to claim 1, wherein the target optical element includes a reflective component, and the laser device further comprises: a wavelength conversion component, the reflective component and the wavelength conversion component are located on the substrate and enclosed by the first frame;
wherein the reflective component is located on the light exit side of the light-emitting chip; the reflective component is in a shape of a prism, and a surface of the reflective component proximate to the light-emitting chip is an inclined surface, and the inclined surface faces toward a side away from the substrate; the wavelength conversion component is disposed on the inclined surface;
the laser beams emitted by the light-emitting chip are directed toward the wavelength conversion component, the wavelength conversion component is configured to emit fluorescence toward the first cover under excitation of the laser beams, the first cover is configured to transmit the fluorescence, a color of the fluorescence is different from a color of the laser beams.

6. The laser device according to claim 5, further satisfying at least one of following:
the inclined surface is a reflective surface, or a surface of the wavelength conversion component proximate to the inclined surface is a reflective surface;
wherein the reflective surface is configured to reflect the fluorescence in a direction away from the substrate;
or
an area of the wavelength conversion component is less than an area of the inclined surface.

7. The laser device according to claim 5, wherein
the first frame includes an annular plate, and a plurality of first side walls disposed on the annular plate and connected in sequence, the annular plate is provided with a conductive structure communicating with an inside and outside of a region enclosed by the first frame;
wherein the substrate is enclosed by the annular plate, and an inner annular surface of the annular plate is fixed to a side of the substrate; the light-emitting chip is disposed on the substrate, and the light-emitting chip is electrically connected to the conductive structure; the reflective component is spaced apart from one of the plurality of first side walls located on the light exit side of the light-emitting chip.

8. The laser device according to claim 5, wherein the first frame includes a first first side wall, a second first side wall and a third first side wall connected in sequence;
the second first side wall is opposite to the reflective component, and the first first side wall and the third first side wall are fixed to two surfaces of the reflective component located on opposite sides of the inclined surface respectively.

9. The laser device according to claim 8, wherein the substrate and the reflective component are a one-piece member, the reflective component is located at an edge of the substrate located on the light-emitting side of the light-emitting chip, and a surface of the reflective component away from the light-emitting chip is flush with the edge of the substrate.

10. The laser device according to claim 9, wherein the first frame satisfies at least one of following:
the first frame further includes a first connecting portion, the first connecting portion being connected the first first side wall and the third first side wall, and fixed to a surface of the reflective component away from the substrate;
wherein a surface of the first connecting portion away from the reflective component and the surfaces of the first first side wall, the second first side wall and the third first side wall away from the substrate constitute a flat annular surface, and the first cover is fixed to the annular surface;
or
the first frame further includes a second connecting portion, the second first side wall is located on the second connecting portion; a surface of the substrate proximate to the second first side wall is fixed to a surface of the second connecting portion, and the two surfaces of the substrate connected to the surface are fixed to the first first side wall and the third first side wall respectively;
wherein the second connecting portion is provided with a conductive structure communicating with an inside and outside of a region enclosed by the first frame, and the light-emitting chip is electrically connected to the conductive structure.

11. The laser device according to claim 10, further comprising a first collimating component, the laser beams emitted by the light-emitting chip is directed toward the first collimating component, and the first collimating component is configured to collimate the received laser beams and then direct the collimated laser beams toward the wavelength conversion component, and the first collimating component satisfies one of following:
the first collimating component includes a collimating lens, the collimating lens is located in the first accommodating space and on a side of the target side wall away from the light-emitting chip; wherein the laser beams exited from the packaging structure is directed toward the collimating lens; and
the first collimating component includes a convex curved surface, the convex curved surface is disposed on the target side wall and is configured to protrude toward an inside of the second accommodating space or outside of the second accommodating space.

12. The laser device according to claim 10, wherein the at least one packaging structure includes a plurality of packaging structures, the at least one light-emitting chip includes a plurality of first light-emitting chips, the plurality of packaging structures are provided in correspondence with the plurality of light-emitting chips;
wherein arrangement positions of the plurality of packaging structures in the first accommodating space are symmetrical about a target axis, the target axis is a straight line passing through a center of the wavelength conversion component and parallel to the substrate, and the plurality of light-emitting chips are configured to emit lasers beams toward the wavelength conversion component.

13. The laser device according to claim 12, wherein the at least one packaging structure includes two packaging structures, the at least one light-emitting chip includes two light-emitting chips, the two packaging structures are provided in correspondence with the two light-emitting chips, the two packaging structures are disposed obliquely on the substrate, and the arrangement positions of the two packaging structures are symmetrical about the target axis.

14. The laser device according to claim 2, wherein the target optical element includes a reflective component, and the reflective component is located in the first accommodating space and on a side of the target side wall away from the light-emitting chip;
wherein the laser beams exited from the packaging structure is directed toward the reflective component, the reflective component is configured to reflect the received laser beams toward the first cover in a direction away from the substrate, and the first cover is further configured to transmit the received laser beams;
the wavelength conversion component satisfies one of following:
the wavelength conversion component is located between the packaging structure and the reflective component; and
the wavelength conversion component is located between the reflective component and the first cover.

15. The laser device according to claim 1, wherein the packaging structure satisfies one of following:
the packaging structure includes:
a second frame, the second frame including the target side wall and at least one second side wall connected to the target side wall; the second frame being fixed to the substrate, the light-emitting chip being disposed on the substrate and enclosed by the second frame; and
a second cover, the second cover being fixed to a side of the second frame away from the substrate;
wherein the second accommodating space is defined by the substrate, the second frame and the second cover; and
the packaging structure includes:
a base plate;
a second frame, the second frame being fixed to the base plate, the second frame including the target side wall and a plurality of second side walls connected to the target side wall, the light-emitting chip being disposed on the substrate and enclosed by the second frame; and
a second cover, the second cover being fixed to a side of the second frame away from the substrate;
wherein the second accommodating space is defined by the base plate, the second frame and the second cover.

16. The laser device according to claim 14, wherein
the first frame includes a plurality of first side walls connected in sequence, one of the plurality of first side walls opposite to the target side wall is provided with a sealing step protruding toward the first accommodating space, and a surface of the second cover proximate to the substrate being fixed to the sealing step.

17. The laser device of claim 1, wherein the target optical element includes a reflective component, the reflective component is configured to reflect the received laser beams in a direction away from the substrate;
the laser device satisfies at least one of following:
the target side wall is further configured to collimate the received laser beams and direct the collimated laser beams toward the reflective component, wherein the target side wall includes a convex curved surface, and the convex curved surface is configured to protrude toward an inside of the second accommodating space or outside of the second accommodating space; and
the laser device further comprise a second collimating component, the second collimating component is located on a side of the first frame away from the substrate, the laser beams reflected by the reflective component are directed toward the second collimating component, and the second collimating component is configured to collimate the received laser beams and then exit the collimated laser beams.

18. The laser device according to claim 1, wherein the target optical element includes a second collimating component and a reflective component, the laser beams emitted by the light-emitting chip is directed toward the second collimating component after passing through the target side wall, the second collimating component is configured to collimate the received laser beams and direct the collimated laser beams toward the reflective component, and the reflective component is configured to reflect the received laser beams in a direction away from the substrate.

19. The laser device according to claim 1, wherein the target optical element includes a second collimating component; an opening is provided on a first side wall of the first frame located on a side of the target optical element away from the light-emitting chip, and the laser device further comprises a light-transmitting layer covering the opening;
the second collimating component is configured to collimate the received laser beams and direct the collimated laser beams toward the light-transmitting layer, and the light-transmitting layer is configured to transmit the received laser beams out of the first accommodating space.

20. The laser device according to claim 1, further comprising a heat sink, wherein
the heat sink is located in the second accommodating space, and the at least one light-emitting chip is located on a side of the heat sink away from the substrate;
a limiting boss is provided at an end of the heat sink proximate to the target side wall, the limiting boss abuts against the target side wall and is located outside a region where the at least one light-emitting chip is provided.
